(19) United States
(12) Patent Application Publication
(10) Pub. No.: US 2014/0162434 A1
(43) Pub. Date: Jun. 12, 2014

(54) DICING TAPE INTEGRATED ADHESIVE SHEET, METHOD OF MANUFACTURING SEMICONDUCTOR DEVICE USING DICING TAPE INTEGRATED ADHESIVE SHEET, AND SEMICONDUCTOR DEVICE

(71) Applicant: NITTO DENKO CORPORATION, Osaka (JP)

(72) Inventors: Goji SHIGA, Ibaraki-shi (JP); Koji MIZUNO, Ibaraki-shi (JP); Naohide TAKAMOTO, Ibaraki-shi (JP)

(73) Assignee: NITTO DENKO CORPORATION, Osaka (JP)

(21) Appl. No.: 14/056,596

(22) Filed: Oct. 17, 2013

(30) Foreign Application Priority Data
Dec. 10, 2012 (JP) 2012-269585
Dec. 10, 2012 (JP) 2012-269586
Dec. 10, 2012 (JP) 2012-269591
Dec. 10, 2012 (JP) 2012-269592
Dec. 10, 2012 (JP) 2012-269596
Apr. 19, 2013 (JP) 2013-088564
Apr. 19, 2013 (JP) 2013-088565
Apr. 19, 2013 (JP) 2013-088566
Apr. 19, 2013 (JP) 2013-088567
Apr. 19, 2013 (JP) 2013-088568

(51) Int. Cl. H01L 21/683; H01L 21/78

(52) U.S. Cl. CPC H01L 21/6836; H01L 21/78
USPC 438/464; 428/40.1

(57) ABSTRACT

A dicing tape integrated adhesive sheet including a substrate, a dicing tape in which a pressure-sensitive adhesive layer is laminated on the substrate, and an adhesive sheet formed on the pressure-sensitive adhesive layer, wherein a peeling force between the pressure-sensitive adhesive layer and the adhesive sheet is 0.02 to 0.5 N/20 mm obtained with a peeling test at a peeling rate of 10 m/minute and a peeling angle of 150°, and an absolute value of a peeling electrification voltage is 0.5 kV or less when the pressure-sensitive adhesive layer and the adhesive sheet are peeled off under conditions of the peeling test.

### BACKGROUND OF THE INVENTION

1. Field of the Invention

The present invention relates to a dicing tape integrated adhesive sheet, a method of manufacturing a semiconductor device using the dicing tape integrated adhesive sheet, and a semiconductor device.

2. Description of the Related Art

In recent years, thinning and downsizing of a semiconductor device and its packaging have been further required. Because of that, a flip-chip semiconductor device, in which a semiconductor element such as a semiconductor chip is mounted on a substrate by flip-chip bonding (flip-chip bonded), has been widely used as a semiconductor device and its packaging. In the flip-chip bonding, the circuit surface of the semiconductor chip is fixed to an electrode forming surface of the substrate in a way that the circuit surface is facing to the electrode forming surface. In such a semiconductor device or the like, a rear surface of the semiconductor chip may be protected by a protective film to prevent the semiconductor chip from being damaged, or the like.

There has previously been a dicing tape integrated film for a rear surface of a semiconductor (see, for example, JP-A-2011-228496), in which a film for a rear surface of a flip-chip semiconductor is laminated on a dicing tape as a protective film. In a process of manufacturing a semiconductor device using the dicing tape integrated film for a rear surface of a semiconductor, first, a semiconductor wafer is bonded and fixed on the film for a rear surface of a flip-chip semiconductor of the dicing tape integrated film for a rear surface of a semiconductor, and then dicing is performed on the semiconductor wafer in this state. The semiconductor wafer is diced into semiconductor chips each having a prescribed size. Then, pickup of the semiconductor chip is performed to peel off the semiconductor chip that is fixed to the dicing tape integrated film for a rear surface of a semiconductor together with the film for a rear surface of a flip-chip semiconductor.

In manufacturing a semiconductor device, for example, a dicing tape integrated adhesive sheet may be used in which a die bond film, an underfill sheet, and the like are laminated on the dicing tape besides the film for a rear surface of a flip-chip semiconductor. The die bond film is a film for die bonding a semiconductor chip to an adherend, and the underfill sheet is a sheet for sealing the space between the circuit surface of a semiconductor chip and the electrode forming surface of a substrate in the flip-chip semiconductor device.

However, when a semiconductor device is manufactured using the dicing tape integrated adhesive sheet, there has previously been a case where breakdown occurs of the circuit that is formed on a semiconductor element such as a semiconductor chip.

### SUMMARY OF THE INVENTION

The present inventors have investigated causes of the circuit breakdown on the semiconductor element. As a result, it has been found out that when a semiconductor element, in which an adhesive sheet such as a film for a rear surface of a flip-chip semiconductor, a die bond film, or an underfill sheet is attached, is peeled off from a dicing tape in the pickup step, peeling electrification is generated between the adhesive sheet and the dicing tape, and that the circuit breakdown on the semiconductor element may occur due to the static electricity generated.

The present inventors have investigated to solve the previous problem, and as a result, found that when the peeling force between a pressure-sensitive adhesive layer of the dicing tape and the adhesive sheet is made to be in a prescribed range and the absolute value of the peeling electrification voltage during peeling is made to be in a prescribed range, breakdown of the circuit on the semiconductor element is suppressed. This finding has led to completion of a first aspect of the present invention.

That is, the first aspect of the present invention is a dicing tape integrated adhesive sheet having a substrate, a dicing tape in which a pressure-sensitive adhesive layer is laminated on the substrate, and an adhesive sheet formed on the pressure-sensitive adhesive layer, wherein

a peeling force between the pressure-sensitive adhesive layer and the adhesive sheet is 0.02 to 0.5 N/20 mm obtained with a peeling test at a peeling rate of 10 m/minute and a peeling angle of 150°, and

an absolute value of a peeling electrification voltage is 0.5 kV or less when the pressure-sensitive adhesive layer and the adhesive sheet are peeled off under conditions of the peeling test.

According to the configuration, the peeling force between the pressure-sensitive adhesive layer and the adhesive sheet is 0.02 to 0.5 N/20 mm obtained with a peeling test at a peeling rate of 10 m/minute and a peeling angle of 150°. Because the peeling force is 0.02 N/20 mm or more, the semiconductor wafer can be fixed during dicing. Moreover, because the peeling force is 0.5 N/20 mm or less, a semiconductor element with the adhesive sheet can be easily peeled off from the pressure-sensitive adhesive layer at the time of pickup. Because the absolute value of a peeling electrification voltage is 0.5 kV or less when the pressure-sensitive adhesive layer and the adhesive sheet are peeled off under conditions of the peeling test, an antistatic effect can be exhibited. As a result, breakdown of the semiconductor element caused by the peeling electrification during pickup is prevented, and the reliability as a device can be improved.

In the configuration, the adhesive sheet is preferably a film for a rear surface of a flip-chip semiconductor to be formed on a rear surface of a semiconductor element that is flip-chip bonded on an adherend. When the adhesive sheet is a film for a rear surface of a flip-chip semiconductor, the film for a rear surface of a flip-chip semiconductor is formed on the rear surface of a semiconductor element, and the circuit surface of the semiconductor element is exposed. However, the absolute value of a peeling electrification voltage is 0.5 kV or less when the pressure-sensitive adhesive layer and the adhesive sheet are peeled off under conditions of the peeling test. As a result, breakdown of the exposed circuit surface of the semiconductor element caused by the peeling electrification can be prevented.

In the configuration, an antistatic agent is preferably contained in the substrate. When the dicing tape is removed from a suction table that fixes the dicing tape after dicing, the peeling electrification may occur between the dicing tape and the suction table. If an antistatic agent is contained in the substrate, the peeling electrification between the substrate and the suction table can be suppressed.

In the configuration, the substrate preferably has a multilayered structure, and an antistatic agent is preferably contained in at least one of outermost layers of the multilayered substrate. When an antistatic agent is contained in the outermost layer of the pressure-sensitive adhesive layer side of the multilayered substrate, electrification of both the substrate and the pressure-sensitive adhesive layer can be suppressed. When an antistatic agent is contained in the outermost layer that is opposite the pressure-sensitive adhesive layer side of the multilayered substrate, the peeling electrification between the substrate and the suction table can be more effectively suppressed.

In the configuration, an antistatic agent layer containing an antistatic agent is preferably formed on at least one surface of the substrate. When the antistatic agent layer is formed on the surface of the pressure-sensitive adhesive layer side of the substrate, the electrification of both the substrate and the pressure-sensitive adhesive layer can be suppressed. When the antistatic agent layer is formed on the surface that is opposite the pressure-sensitive adhesive layer side of the substrate, the peeling electrification between the substrate and the suction table can be more effectively suppressed.

In the configuration, an antistatic agent is preferably contained in the pressure-sensitive adhesive layer. When an antistatic agent is contained in the pressure-sensitive adhesive layer, the peeling electrification generated when the pressure-sensitive adhesive layer and the adhesive sheet are peeled off can be more effectively suppressed.

In the configuration, an antistatic agent is preferably contained in the adhesive sheet. When an antistatic agent is contained in the adhesive sheet, the adhesive sheet has an antistatic effect even after it is peeled off from the dicing tape. As a result, breakdown of the semiconductor element caused by electrification can be suppressed even after the adhesive sheet is peeled off from the dicing tape.

The first aspect of the present invention is a method of manufacturing a semiconductor device using the dicing tape integrated adhesive sheet, the method including the steps of:

bonding a semiconductor wafer onto the adhesive sheet of the dicing tape integrated adhesive sheet,

dicing the semiconductor wafer to form a semiconductor element, and

picking up the semiconductor element from the pressure-sensitive adhesive layer of the dicing tape together with the adhesive sheet.

According to the configuration, the dicing tape integrated adhesive sheet is used. Therefore, the peeling force between the pressure-sensitive adhesive layer and the adhesive sheet is 0.02 to 0.5 N/20 mm. Because the peeling force is 0.02 N/20 mm or more, the semiconductor wafer can be fixed during dicing. Moreover, because the peeling force is 0.5 N/20 mm or less, a semiconductor element with the adhesive sheet can be easily peeled off from the pressure-sensitive adhesive layer at the time of pickup. Because the absolute value of the peeling electrification voltage is 0.5 kV or less when peeling is performed under the peeling test, an antistatic effect can be exhibited. As a result, breakdown of the semiconductor element caused by the peeling electrification during pickup is prevented, and the reliability as a device can be improved.

The semiconductor device according to the first aspect of the present invention is characterized to be manufactured using the dicing tape integrated adhesive sheet in order to solve the above-described problem.

The present inventors have investigated to solve the previous problem, and as a result, found that when the surface resistivity of at least one surface of the substrate and pressure-sensitive adhesive layer of the dicing tape is made to be in a prescribed range, breakdown of the circuit on the semiconductor element is suppressed. This finding has led to completion of a second aspect of the present invention.

That is, the second aspect of the present invention is a dicing tape integrated adhesive sheet having a substrate, a dicing tape in which a pressure-sensitive adhesive layer is laminated on the substrate, and an adhesive sheet formed on the pressure-sensitive adhesive layer, wherein

at least one surface of the substrate and the pressure-sensitive adhesive layer has a surface resistivity of 1.0×10¹¹Ω or less.

According to the configuration, because at least one surface of the substrate and the pressure-sensitive adhesive layer has a surface resistivity of 1.0×10¹¹Ω or less, the electrification less likely occurs. Therefore, an antistatic effect can be exhibited. As a result, breakdown of the semiconductor element caused by the peeling electrification during pickup is prevented, and the reliability as a device can be improved.

In the configuration, the adhesive sheet is preferably a film for a rear surface of a flip-chip semiconductor to be formed on a rear surface of a semiconductor element that is flip-chip bonded on an adherend. When the adhesive sheet is a film for a rear surface of a flip-chip semiconductor, the film for a rear surface of a flip-chip semiconductor is formed on the rear surface of a semiconductor element, and the circuit surface of the semiconductor element is exposed. However, at least one surface of the substrate and the pressure-sensitive adhesive layer has a surface resistivity of 1.0×10¹¹Ω or less. As a result, breakdown of the exposed circuit surface of the semiconductor element caused by the peeling electrification can be prevented.

In the configuration, an antistatic agent is preferably contained in the substrate. When the dicing tape is removed from a suction table that fixes the dicing tape after dicing, the peeling electrification may occur between the dicing tape and the suction table. If an antistatic agent is contained in the substrate, the peeling electrification between the substrate and the suction table can be suppressed.

In the configuration, the substrate preferably has a multilayered structure, and an antistatic agent is preferably contained in at least one of outermost layers of the multilayered substrate. When an antistatic agent is contained in the outermost layer of the pressure-sensitive adhesive layer side of the multilayered substrate, electrification of both the substrate and the pressure-sensitive adhesive layer can be suppressed. When an antistatic agent is contained in the outermost layer that is opposite the pressure-sensitive adhesive layer side of the multilayered substrate, the peeling electrification between the substrate and the suction table can be more effectively suppressed.

In the configuration, an antistatic agent layer containing an antistatic agent is preferably formed on at least one surface of the substrate. When the antistatic agent layer is formed on the surface of the pressure-sensitive adhesive layer side of the substrate, the electrification of both the substrate and the pressure-sensitive adhesive layer can be suppressed. When the antistatic agent layer is formed on the surface that is opposite the pressure-sensitive adhesive layer of the substrate, the peeling electrification between the substrate and the suction table can be more effectively suppressed.

In the configuration, an antistatic agent is preferably contained in the pressure-sensitive adhesive layer. When an antistatic agent is contained in the pressure-sensitive adhesive layer, the peeling electrification generated when the pressure-sensitive adhesive layer and the adhesive sheet are peeled off can be more effectively suppressed.

In the configuration, the antistatic agent is preferably a polymeric antistatic agent. If the antistatic agent is a polymeric antistatic agent, bleeding of the agent from the substrate or the pressure-sensitive adhesive layer less likely occurs. As a result, a decrease in antistatic function over time can be suppressed.

The second aspect of the present invention is a method of manufacturing a semiconductor device using the dicing tape integrated adhesive sheet, the method including the steps of:

bonding a semiconductor wafer onto the adhesive sheet of the dicing tape integrated adhesive sheet,

dicing the semiconductor wafer to form a semiconductor element, and

picking up the semiconductor element from the pressure-sensitive adhesive layer of the dicing tape together with the adhesive sheet.

According to the configuration, the dicing tape integrated adhesive sheet is used. Therefore, at least one surface of the substrate and the pressure-sensitive adhesive layer has a surface resistivity of 1.0×10¹¹Ω or less. Because the surface resistivity is 1.0×10¹¹Ω or less, an antistatic effect can be exhibited. As a result, breakdown of the semiconductor element caused by the peeling electrification during pickup is prevented, and the reliability as a device can be improved.

The present inventors have investigated in order to solve the previous problem, and as a result, found that when a polymeric antistatic agent is contained in at least one of the substrate and pressure-sensitive adhesive layer of the dicing tape, breakdown of the circuit on the semiconductor element is suppressed. This finding has led to completion of a third aspect of the present invention.

That is, the third aspect of the present invention is a dicing tape integrated adhesive sheet having a substrate, a dicing tape in which a pressure-sensitive adhesive layer is laminated on the substrate, and an adhesive sheet formed on the pressure-sensitive adhesive layer, wherein

a polymeric antistatic agent is contained in at least one of the substrate and the pressure-sensitive adhesive layer.

According to the configuration, because a polymeric antistatic agent is contained in at least one of the substrate and the pressure-sensitive adhesive layer, the electrification less likely occurs. Therefore, an antistatic effect can be exhibited. Because a polymeric antistatic agent is used as the antistatic agent, bleeding of the agent from the substrate or the pressure-sensitive adhesive layer less likely occurs. As a result, a decrease in antistatic function over time can be suppressed.

In the configuration, the adhesive sheet is preferably a film for a rear surface of a flip-chip semiconductor to be formed on a rear surface of a semiconductor element that is flip-chip bonded on an adherend. When the adhesive sheet is a film for a rear surface of a flip-chip semiconductor, the film for a rear surface of a flip-chip semiconductor is formed on the rear surface of a semiconductor element, and the circuit surface of the semiconductor element is exposed. However, a polymeric antistatic agent is contained in at least one of the substrate and the pressure-sensitive adhesive layer. As a result, breakdown of the exposed circuit surface of the semiconductor element caused by the peeling electrification can be prevented.

In the configuration, the substrate preferably has a multilayered structure, and an antistatic agent is preferably contained in at least one of outermost layers of the multilayered substrate. When an antistatic agent is contained in the outermost layer of the pressure-sensitive adhesive layer side of the multilayered substrate, electrification of both the substrate and the pressure-sensitive adhesive layer can be suppressed. When an antistatic agent is contained in the outermost layer that is opposite the pressure-sensitive adhesive layer side of the multilayered substrate, the peeling electrification between the substrate and the suction table can be more effectively suppressed.

In the configuration, an antistatic agent layer containing an antistatic agent is preferably formed on at least one surface of the substrate. When the antistatic agent layer is formed on the surface of the pressure-sensitive adhesive layer side of the substrate, the electrification of both the substrate and the pressure-sensitive adhesive layer can be suppressed. When the antistatic agent layer is formed on the surface opposite the pressure-sensitive adhesive layer side of the substrate, the peeling electrification between the substrate and the suction table can be more effectively suppressed.

The third aspect of the present invention is a method of manufacturing a semiconductor device using the dicing tape integrated adhesive sheet, the method including the steps of:

bonding a semiconductor wafer onto the adhesive sheet of the dicing tape integrated adhesive sheet,

dicing the semiconductor wafer to form a semiconductor element, and

picking up the semiconductor element from the pressure-sensitive adhesive layer of the dicing tape together with the adhesive sheet.

According to the configuration, the dicing tape integrated adhesive sheet is used. Therefore, a polymeric antistatic agent is contained in at least one of the substrate and the pressure-sensitive adhesive layer. Because a polymeric antistatic agent is contained in at least one of the substrate and the pressure-sensitive adhesive layer, an antistatic effect can be exhibited. As a result, breakdown of the semiconductor element caused by the peeling electrification during pickup is prevented, and the reliability as a device can be improved. Because a polymeric antistatic agent is used as the antistatic agent, bleeding of the agent from the substrate or the pressure-sensitive adhesive layer less likely occurs. As a result, a decrease in antistatic function over time can be suppressed.

The present inventors have investigated in order to solve the previous problem, and as a result, found that when the surface resistivity of any surface of the adhesive sheet used in manufacturing of a semiconductor device is made to be in a prescribed range, breakdown of the circuit on the semiconductor element is suppressed. This finding has led to completion of a fourth aspect of the present invention.

That is, the adhesive sheet according to the fourth aspect of the present invention is an adhesive sheet used in manufacturing of a semiconductor device, wherein any surface of the adhesive sheet has a surface resistivity of 1.0×10¹¹Ω or less.

According to the configuration, because any surface of the adhesive sheet has a surface resistivity of 1.0×10¹¹Ω or less, the electrification less likely occurs. Therefore, an antistatic effect can be exhibited. As a result, when the adhesive sheet is bonded to the dicing tape and used as the dicing tape integrated adhesive sheet, breakdown of the semiconductor element caused by the peeling electrification during pickup is prevented, and the reliability as a device can be improved.

In the configuration, the adhesive sheet is preferably a film for a rear surface of a flip-chip semiconductor to be formed on a rear surface of a semiconductor element that is flip-chip bonded on an adherend. When the adhesive sheet is a film for a rear surface of a flip-chip semiconductor, the film for a rear surface of a flip-chip semiconductor is formed on the rear surface of a semiconductor element, and the circuit surface of the semiconductor element is exposed. However, any surface of the film for a rear surface of a flip-chip semiconductor has a surface resistivity of 1.0×10¹¹Ω or less. As a result, breakdown of the exposed circuit surface of the semiconductor element caused by the peeling electrification can be prevented.

In the configuration, an antistatic agent is preferably contained in the adhesive sheet. When an antistatic agent is contained in the adhesive sheet, the adhesive sheet has an antistatic effect even after it is peeled off from the dicing tape. As a result, breakdown of the semiconductor element caused by electrification can be suppressed even after the adhesive sheet is peeled off from the dicing tape.

The dicing tape integrated adhesive sheet according to the fourth aspect of the present invention has a substrate, a dicing tape in which a pressure-sensitive adhesive layer is laminated on the substrate, and the adhesive sheet, wherein the adhesive sheet is formed on the pressure-sensitive adhesive layer.

According to the configuration, because any surface of the adhesive sheet has a surface resistivity of 1.0×10¹¹Ω or less, the electrification less likely occurs. Therefore, an antistatic effect can be exhibited. As a result, breakdown of the semiconductor element caused by the peeling electrification during pickup is prevented, and the reliability as a device can be improved.

The fourth aspect of the present invention is a method of manufacturing a semiconductor device using the adhesive sheet, the method including the steps of:

preparing a dicing tape in which a pressure-sensitive adhesive layer is laminated on a substrate,

bonding the adhesive sheet onto the pressure-sensitive adhesive layer of the dicing tape to obtain a dicing tape integrated adhesive sheet,

bonding a semiconductor wafer onto the adhesive sheet of the dicing tape integrated adhesive sheet,

dicing the semiconductor wafer to form a semiconductor element, and

picking up the semiconductor element from the pressure-sensitive adhesive layer of the dicing tape together with the adhesive sheet.

The fourth aspect of the present invention is a method of manufacturing a semiconductor device using the dicing tape integrated adhesive sheet, the method including the steps of:

bonding a semiconductor wafer onto the adhesive sheet of the dicing tape integrated adhesive sheet,

dicing the semiconductor wafer to form a semiconductor element, and

picking up the semiconductor element from the pressure-sensitive adhesive layer of the dicing tape together with the adhesive sheet.

According to the configuration, the adhesive sheet or the dicing tape integrated adhesive sheet is used. Therefore, any surface of the adhesive sheet has a surface resistivity of 1.0×10¹¹Ω or less. Because the surface resistivity is 1.0×10¹¹Ω or less, an antistatic effect can be exhibited. As a result, breakdown of the semiconductor element caused by the peeling electrification during pickup is prevented, and the reliability as a device can be improved.

The semiconductor device according to the fourth aspect of the present invention is characterized to be manufactured by using the adhesive sheet in order to solve the above-described problem.

The semiconductor device according to the fourth aspect of the present invention is characterized to be manufactured by using the dicing tape integrated adhesive sheet in order to solve the above-described problem.

The present inventors have investigated in order to solve the previous problem, and as a result, found that when a polymeric antistatic agent is contained in the adhesive sheet used in manufacturing of a semiconductor device, breakdown of the circuit on the semiconductor element is suppressed. This finding has led to completion of a fifth aspect of the present invention.

That is, the adhesive sheet according to the fifth aspect of the present invention is an adhesive sheet used in manufacturing of a semiconductor device, wherein a polymeric antistatic agent is contained in the adhesive sheet.

According to the configuration, because a polymeric antistatic agent is contained in the adhesive sheet, the electrification less likely occurs. Therefore, an antistatic effect can be exhibited. Because a polymeric antistatic agent is used as the antistatic agent, bleeding of the agent from the adhesive sheet less likely occurs. As a result, a decrease in antistatic function over time can be suppressed. Because a polymeric antistatic agent is contained in the adhesive sheet, the adhesive sheet has an antistatic effect even after it is peeled off from the dicing tape when it is bonded to the dicing tape to be used as the dicing tape integrated adhesive sheet. As a result, breakdown of the semiconductor element caused by electrification can be suppressed even after the adhesive sheet is peeled off from the dicing tape.

In the configuration, the adhesive sheet is preferably a film for a rear surface of a flip-chip semiconductor to be formed on a rear surface of a semiconductor element that is flip-chip bonded on an adherend. When the adhesive sheet is a film for a rear surface of a flip-chip semiconductor, the film for a rear surface of a flip-chip semiconductor is formed on the rear surface of a semiconductor element, and the circuit surface of the semiconductor element is exposed. However, a polymeric antistatic agent is contained in the adhesive sheet. As a result, breakdown of the exposed circuit surface of the semiconductor element caused by the peeling electrification can be prevented.

The dicing tape integrated adhesive sheet according to the fifth aspect of the present invention has a substrate, a dicing tape in which a pressure-sensitive adhesive layer is laminated on the substrate, and an adhesive sheet formed on the pressure-sensitive adhesive layer, wherein the adhesive sheet is formed on the pressure-sensitive adhesive layer.

According to the configuration, because a polymeric antistatic agent is contained in the adhesive sheet, the electrification less likely occurs. Therefore, an antistatic effect can be exhibited. As a result, breakdown of the semiconductor element caused by the peeling electrification during pickup is prevented, and the reliability as a device can be improved. Because a polymeric antistatic agent is used as the antistatic agent, bleeding of the agent from the adhesive sheet less likely occurs. As a result, a decrease in antistatic function over time can be suppressed. Because a polymeric antistatic agent is contained in the adhesive sheet, the adhesive sheet has an antistatic effect even after it is peeled off from the dicing tape. As a result, breakdown of the semiconductor element caused by electrification can be suppressed even after the adhesive sheet is peeled off from the dicing tape.

The fifth aspect of the present invention is a method of manufacturing a semiconductor device using the adhesive sheet, the method including the steps of:

preparing a dicing tape in which a pressure-sensitive adhesive layer is laminated on a substrate,

bonding the adhesive sheet onto the pressure-sensitive adhesive layer of the dicing tape to obtain a dicing tape integrated adhesive sheet,

bonding a semiconductor wafer onto the adhesive sheet of the dicing tape integrated adhesive sheet,

dicing the semiconductor wafer to form a semiconductor element, and

picking up the semiconductor element from the pressure-sensitive adhesive layer of the dicing tape together with the adhesive sheet.

The fifth aspect of the present invention is a method of manufacturing a semiconductor device using the dicing tape integrated adhesive sheet, the method including the steps of:

bonding a semiconductor wafer onto the adhesive sheet of the dicing tape integrated adhesive sheet,

dicing the semiconductor wafer to form a semiconductor element, and

picking up the semiconductor element from the pressure-sensitive adhesive layer of the dicing tape together with the adhesive sheet.

According to the configuration, the adhesive sheet or the dicing tape integrated adhesive sheet is used. A polymeric antistatic agent is contained in the adhesive sheet, and therefore an antistatic effect can be exhibited. As a result, breakdown of the semiconductor element caused by the peeling electrification during pickup is prevented, and the reliability as a device can be improved. Because a polymeric antistatic agent is used as the antistatic agent, bleeding of the agent from the adhesive sheet less likely occurs. As a result, a decrease in antistatic function over time can be suppressed. Because a polymeric antistatic agent is contained in the adhesive sheet, the adhesive sheet has an antistatic effect even after it is peeled off from the dicing tape. As a result, breakdown of the semiconductor element caused by electrification can be suppressed even after the adhesive sheet is peeled off from the dicing tape.

The semiconductor device according to the fifth aspect of the present invention is characterized to be manufactured by using the adhesive sheet in order to solve the above-described problem.

The semiconductor device according to the fifth aspect of the present invention is characterized to be manufactured by using the dicing tape integrated adhesive sheet in order to solve the above-described problem.

### BRIEF DESCRIPTION OF THE DRAWINGS

FIG. 1 is a schematic sectional view of a dicing tape integrated film for a rear surface of a semiconductor according to the present embodiment;

FIG. 2 is a schematic configuration view for illustrating a method of measuring a peeling electrification voltage;

FIG. 3 is a schematic sectional view of a dicing tape integrated film for a rear surface of a semiconductor according to other embodiments;

FIG. 4 is a schematic sectional view of a dicing tape integrated film for a rear surface of a semiconductor according to other embodiments; and

FIGS. 5 (A) to 5 (D) are schematic sectional views showing one example of a method of manufacturing a semiconductor device using the dicing tape integrated film for a rear surface of a semiconductor according to the present embodiment.

### DESCRIPTION OF REFERENCE SIGNS

1,10,20 Dicing tape integrated film for rear surface of semiconductor
2 Film for rear surface of flip-chip semiconductor (film for rear surface of semiconductor)
3 Dicing tape
31 Substrate
32 Pressure-sensitive adhesive layer
33 Portion that corresponds to bonding portion of semiconductor wafer
35,36 Antistatic agent layer
4 Semiconductor wafer
5 Semiconductor chip
51 Bump that is formed on circuit surface side of semiconductor chip 5
6 Adherend
61 Conductive material for bonding that is attached to connection pad of adherend 6
100 Sample of acrylic plate
102 Sample fixing stage
110 Suction table

### DETAILED DESCRIPTION OF THE PREFERRED EMBODIMENT

### <First Aspect of Present Invention>

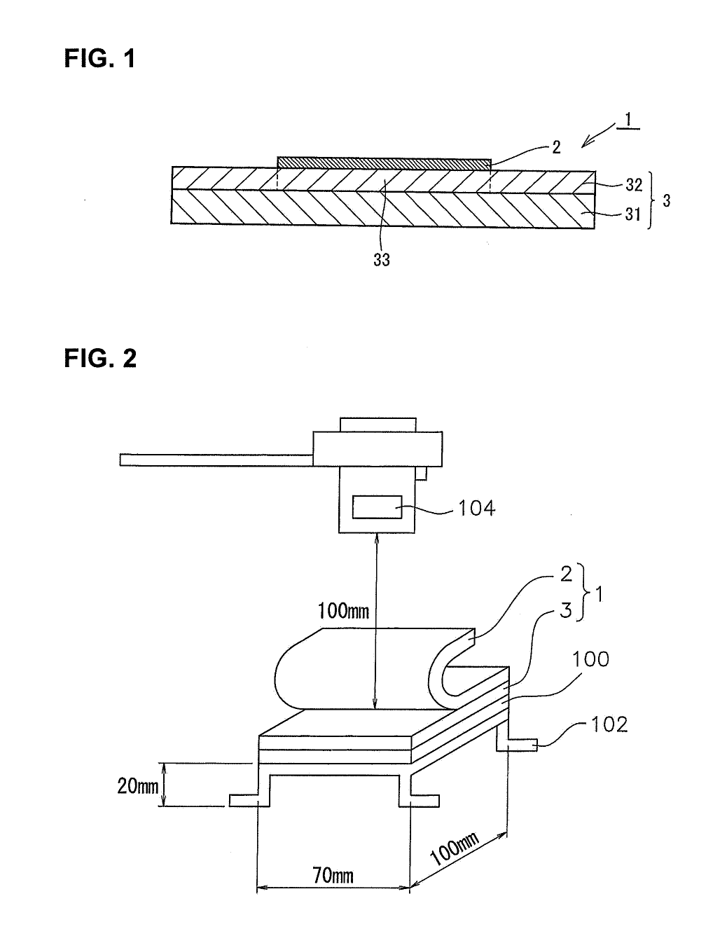

An embodiment of the first aspect of the present invention will be described with reference to the drawings. However, the first aspect of the present invention is not limited to these examples. First, a case will be described below in which the dicing tape integrated adhesive sheet of the first aspect of the present invention is a dicing tape integrated film for a rear surface of a semiconductor. That is, a case will be described in which the adhesive sheet of the first aspect of the present invention is a film for a rear surface of a flip-chip semiconductor. FIG. 1 is a schematic sectional view showing one example of the dicing tape integrated film for a rear surface of a semiconductor according to the present embodiment. In the present specification, parts that are unnecessary for the description are omitted in the drawings, and there are parts that are enlarged or reduced in the drawings to make the description easy.

### (Dicing Tape Integrated Film for Rear Surface of Semiconductor)

As shown in FIG. 1, a dicing tape integrated film 1 for a rear surface of a semiconductor has a configuration of including a substrate 31, a dicing tape 3 in which a pressure-sensitive adhesive layer 32 is provided on the substrate 31, and a film 2 for a rear surface of a flip-chip semiconductor (may be referred to as “a film for a rear surface of a semiconductor” below) provided on the pressure-sensitive adhesive layer 32. As shown in FIG. 1, the dicing tape integrated film for a rear surface of a semiconductor of the first aspect of the present invention may have a configuration in which the film 2 for a rear surface of a semiconductor is formed only on a portion 33 that corresponds to a bonding portion of a semiconductor wafer on the pressure-sensitive adhesive layer 32 of the dicing tape 3; however, it may have a configuration in which the film for a rear surface of a semiconductor is formed on the entire surface of the pressure-sensitive adhesive layer 32, or it may have a configuration in which the film for a rear surface of a semiconductor is formed on a portion larger than the portion 33 that corresponds to the bonding portion of a semiconductor wafer and smaller than the entire surface of the pressure-sensitive adhesive layer 32. The surface (the surface that is bonded to a rear surface of the wafer) of the film 2 for a rear surface of a semiconductor may be protected by a separator or the like until it is bonded to the rear surface of the wafer.

In the dicing tape integrated film 1 for a rear surface of a semiconductor, a peeling force between the pressure-sensitive adhesive layer 32 and the adhesive sheet 2 is 0.02 to 0.5 N/20 mm, preferably 0.02 to 0.3 N/20 mm, and more preferably 0.02 to 0.2 N/20 mm obtained with a peeling test at a peeling rate of 10 m/minute and a peeling angle of 150°. Because the peeling force is 0.02 N/20 mm or more, the semiconductor wafer can be fixed during dicing. Because the peeling force is 0.5 N/20 mm or less, a semiconductor element with the adhesive sheet 2 can be easily peeled off from the pressure-sensitive adhesive layer 32 at the time of pickup.

In the dicing tape integrated film 1 for a rear surface of a semiconductor, an absolute value of a peeling electrification voltage generated when the pressure-sensitive adhesive layer 32 and the adhesive sheet 2 are peeled off under conditions of the peeling test is 0.5 kV or less (−0.5 kV to +0.5 kV), preferably 0.3 kV or less (−0.3 kV to +0.3 kV), and more preferably 0.2 kV or less (−0.2 kV to +0.2 kV). Because the absolute value of a peeling electrification voltage is 0.5 kV or less when the pressure-sensitive adhesive layer 32 and the adhesive sheet 2 are peeled off under conditions of the peeling test, an antistatic effect can be exhibited. As a result, breakdown of the semiconductor element caused by the peeling electrification during pickup is prevented, and the reliability as a device can be improved.

Here, a method of measuring the peeling electrification voltage is described.

FIG. 2 is a schematic configuration view for illustrating the method of measuring the peeling electrification voltage. First, the dicing tape integrated film 1 for a rear surface of a semiconductor is bonded to an acrylic plate 100 (thickness: 1 mm, width: 70 mm, length: 100 mm) that has been destaticized in advance. The bonding is performed using a hand roller so that the acrylic plate 100 and the dicing tape 3 are facing each other with a double-sided pressure-sensitive adhesive tape interposed therebetween. Then, it is allowed to stand in this state under environments of 23° C. and 50% RH for a day. After that, the acrylic plate 100 to which the dicing tape integrated film 1 for a rear surface of a semiconductor is bonded is fixed to a sample fixing stage 102. Next, an end portion of the film 2 for a rear surface of a semiconductor is fixed to an automatic winding machine, and the film is peeled off at a peeling angle of 150° and a peeling rate of 10 m/minute. A potential of the surface of the dicing tape 3 side (the surface of the pressure-sensitive adhesive layer 32) generated at this time is measured with a potential measuring machine 104 (“KSD-0103” manufactured by Kasuga Electric Works Ltd.) fixed at 100 mm from the surface of the dicing tape. The measurement is performed under environments of 23° C. and 50% RH.

In the dicing tape integrated film 1 for a rear surface of a semiconductor, at least any surface of the substrate 31, the pressure-sensitive adhesive layer 32, and the film 2 for a rear surface of a semiconductor has a surface resistivity of preferably 1.0×10¹¹Ω or less, more preferably 1.0×10¹⁰Ω or less, and further preferably 1.0×10⁹Ω or less. The smaller the surface resistivity is, the more preferable it is, and examples of the surface resistivity may include 1.0×10⁵Ω or more, 1.0×10⁶Ω or more, and 1.0×10⁷Ω or more. When the surface resistivity is 1.0×10¹¹Ω or less, the electrification less likely occurs. Therefore, an antistatic effect can be further exhibited. In the first aspect of the present invention, the surface resistivity of at least any surface of the substrate, the pressure-sensitive adhesive layer, and the film for a rear surface of a semiconductor refers to the surface resistivity of at least any of the surface of the substrate of the pressure-sensitive adhesive layer side, the surface of the substrate opposite the pressure-sensitive adhesive layer, the surface of the pressure-sensitive adhesive layer of the substrate side, the surface of the pressure-sensitive adhesive layer opposite the substrate, the surface of the film for a rear surface of a semiconductor of the pressure-sensitive adhesive layer side, and the surface of the film for a rear surface of a semiconductor opposite the pressure-sensitive adhesive layer. The surface resistivity is a value that is measured with a method described in Examples.

In the dicing tape integrated film 1 for a rear surface of a semiconductor, an antistatic agent is preferably contained in at least one of the substrate 31, the pressure-sensitive adhesive layer 32, and the film 2 for a rear surface of a semiconductor.

When an antistatic agent is contained in the substrate 31, the peeling electrification between the substrate 31 and a suction table when the dicing tape 3 is removed from the suction table that fixes the dicing tape 3 can be suppressed. Particularly, when the substrate 31 has a multilayered structure and an antistatic agent is contained in the outermost layer of the pressure-sensitive adhesive layer 32 side of the multilayered substrate 31, the electrification of both the substrate 31 and the pressure-sensitive adhesive layer 32 can be suppressed. When an antistatic agent is contained in the outermost layer opposite the pressure-sensitive adhesive layer 32 of the multilayered substrate 31, the peeling electrification between the substrate 31 and the suction table can be more effectively suppressed.

When an antistatic agent is contained in the pressure-sensitive adhesive layer 32, the peeling electrification generated when the pressure-sensitive adhesive layer 32 and the film 2 for a rear surface of a semiconductor are peeled off can be more effectively suppressed.

When an antistatic agent is contained in the film 2 for a rear surface of a semiconductor, the film 2 has an antistatic effect even after it is peeled off from the dicing tape 3. As a result, breakdown of the semiconductor element caused by electrification can be suppressed even after the film 2 is peeled off from the dicing tape 3. Particularly, when the film 2 for a rear surface of a semiconductor has a multilayered structure and an antistatic agent is contained in the outermost layer of the dicing tape 3 side of the multilayered film 2 for a rear surface of a semiconductor, the peeling electrification generated when the pressure-sensitive adhesive layer 32 and the film 2 for a rear surface of a semiconductor are peeled off can be more effectively suppressed.

Examples of the antistatic agent include cationic antistatic agents having a cationic functional group such as a quaternary ammonium salt, a pyridinium salt, a primary, a secondary, and a tertiary amino group; anionic antistatic agents having an anionic functional group such as sulfonate, sulfate, phosphonate, and phosphate; amphoteric antistatic agents such as alkylbetaine and its derivatives, imidazoline and its derivatives, and alanine and its derivatives; nonionic antistatic agents such as aminoalcohol and its derivatives, glycerin and its derivatives, and polyethylene glycol and its derivatives; and ionically conductive polymers (polymeric antistatic agents) obtained by polymerizing or copolymerizing monomers having the above-described cationic, anionic, and amphoteric ionically conductive groups. These compounds may be used alone or in combination of two or more kinds thereof. Among these, a polymeric antistatic agent is preferable. When a polymeric antistatic agent is used, bleeding of the agent from the substrate 31, the pressure-sensitive adhesive layer 32, and the film 2 for a rear surface of a semiconductor less likely occurs. As a result, a decrease in antistatic function over time can be suppressed.

Specific examples of the cationic antistatic agent include(meth)acrylate copolymers having a quaternary ammonium group such as an alkyltrimethyl ammonium salt, acyloylamidopropyltrimethyl ammonium methosulfate, an alkylbenzylmethyl ammonium salt, choline acyl chloride, and polydimethylaminoethyl methacrylate; styrene copolymers having a quaternary ammonium group such as polyvinylbenzyltrimethyl ammonium chloride; and diallylamine copolymers having a quaternary ammonium group such as polydiallyldimethyl ammonium chloride. These compounds may be used alone or in combination of two or more kinds thereof.

Examples of the anionic antistatic agent include alkyl sulfonate, alkylbenzene sulfonate, alkylsulfate, alkylethoxysulfate, alkyl phosphate, and a sulfonic acid group-containing styrene copolymer. These compounds may be used alone or in combination of two or more kinds thereof.

Examples of the amphoteric antistatic agent include alkylbetaine, alkylimidazoliumbetaine, and a carbobetaine graft copolymer. These compounds may be used alone or in combination of two or more kinds thereof.

Examples of the nonionic antistatic agent include fatty acid alkylolamide, di(2-hydroxyethyl)alkylamine, polyoxyethylene alkylamine, fatty acid glycerol ester, polyoxyethylene glycol fatty acid ester, sorbitan fatty acid ester, polyoxysorbitan fatty acid ester, polyoxyethylene alkylphenylether, polyoxyethylene alkylether, polyethylene glycol, polyoxyethylene diamine, a copolymer including polyether, polyester, and polyamide, methoxypolyethylene glycol(meth)acrylate, and the like. These compounds may be used alone or in combination of two or more kinds thereof.

Other examples of the polymeric antistatic agent include polyaniline, polypyrrole, polythiophene, and the like.

Other examples of the antistatic agent include conductive substances. Examples of the conductive substance include tin oxide, antimony oxide, indium oxide, cadmium oxide, titanium oxide, zinc oxide, indium, tin, antimony, gold, silver, copper, aluminum, nickel, chromium, titanium, iron, cobalt, copper iodide, and alloys and mixtures thereof.

The content of the antistatic agent is preferably 50% by weight or less and more preferably 30% by weight or less to the entire resin component of the layer where the antistatic agent is added. The content of the antistatic agent is preferably 5% by weight or more and more preferably 10% by weight or more to the entire resin component of the layer where the antistatic agent is added. When the antistatic agent is contained within the above-described range, the antistatic function can be given without interfering with the functions of the layer where the antistatic agent in added. Here, “50% by weight or less to the entire resin component of the layer where the antistatic agent is added” means as follows.

(a) When the layer where the antistatic agent is added is the substrate 31

When the substrate 31 is composed of one layer, it means 50% by weight or less to the entire resin component that constitutes the substrate 31.

When the substrate 31 is constituted with a multilayered structure, it means 50% by weight or less to the entire resin component that constitutes one of the multiple layers.

(b) When the layer where the antistatic agent is added is the pressure-sensitive adhesive layer 32

It means 50% by weight or less to the entire resin component that constitutes the pressure-sensitive adhesive layer 32.

(c) When the layer where the antistatic agent is added is the film 2 for a rear surface of a semiconductor

When the film 2 for a rear surface of a semiconductor is composed of one layer, it means 50% by weight or less to the entire resin component that constitutes the film 2 for a rear surface of a semiconductor.

When the film 2 for a rear surface of a semiconductor is constituted with a multilayered structure, it means 50% by weight or less to the entire resin component that constitutes one of the multiple layers.

In regards to “30% by weight or less to the entire resin component of the layer where the antistatic agent is added,” “5% by weight or more to the entire resin component of the layer where the antistatic agent is added,” and “10% by weight or more to the entire resin component of the layer where the antistatic agent is added,” each of them also means a weight percentage to the entire resin component that constitutes a substrate, a pressure-sensitive adhesive layer, or a film for a rear surface of a semiconductor when the substrate, the pressure-sensitive adhesive layer, and the film for a rear surface of a semiconductor are composed of one layer, and a weight percentage to the entire resin component that constitutes one of multiple layers constituting the substrate or the film for a rear surface of a semiconductor when they are constituted with a multilayered structure.

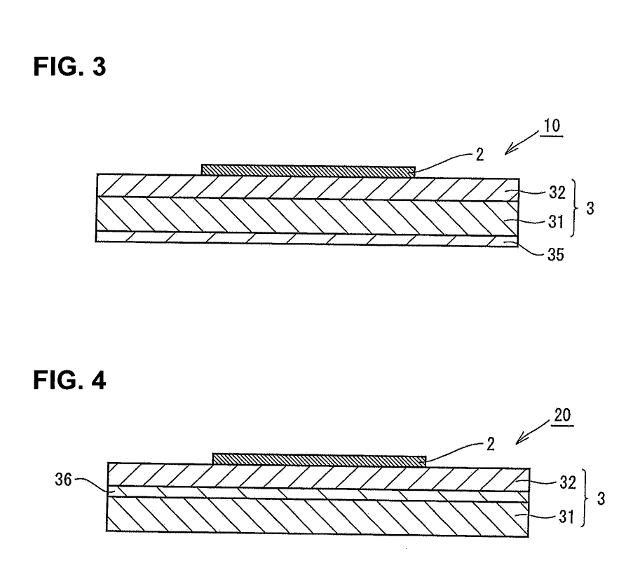

In the dicing tape integrated film for a rear surface of a semiconductor, an antistatic agent layer containing an antistatic agent may be formed on at least one surface of the substrate. FIGS. 3 and 4 are schematic sectional views of a dicing tape integrated film for a rear surface of a semiconductor according to other embodiments.

As shown in FIG. 3, a dicing tape integrated film 10 for a rear surface of a semiconductor has the substrate 31, the dicing tape 3 in which the pressure-sensitive adhesive layer 32 is provided on the substrate 31, the film 2 for a rear surface of a semiconductor provided on the pressure-sensitive adhesive layer 32, and an antistatic agent layer 35 formed on a surface that is opposite the pressure-sensitive adhesive layer 32 of the substrate 31. Because the antistatic agent layer 35 is formed on the surface that is opposite the pressure-sensitive adhesive layer 32 of the substrate 31 in the dicing tape integrated film 10 for a rear surface of a semiconductor, the peeling electrification between the substrate 31 and the suction table can be more effectively suppressed.

As shown in FIG. 4, a dicing tape integrated film 20 for a rear surface of a semiconductor has a configuration including the substrate 31, the dicing tape 3 in which the pressure-sensitive adhesive layer 32 is provided on the substrate 31, an antistatic agent layer 36 provided between the substrate 31 and the pressure-sensitive adhesive layer 32, and the film 2 for a rear surface of a semiconductor provided on the pressure-sensitive adhesive layer 32. Because the antistatic agent layer 36 is formed on the surface of the pressure-sensitive adhesive layer 32 side of the substrate 31 in the dicing tape integrated film 20 for a rear surface of a semiconductor, the electrification of both the substrate 31 and the pressure-sensitive adhesive layer 32 can be suppressed.

### (Antistatic Agent Layer)

The antistatic agent layers 35 and 36 contain at least an antistatic agent. The same agents as those contained in the substrate 31, the pressure-sensitive adhesive layer 32, and the film 2 for a rear surface of a semiconductor can be used as the antistatic agent contained in the antistatic agent layers 35 and 36. A binder component, a solvent, and the like may be contained in the antistatic agent layers 35 and 36 besides the antistatic agent as necessary.

The thicknesses of the antistatic agent layers 35 and 36 are preferably 0.01 to 5 μm and more preferably 0.03 to 1 μm. When the thicknesses of the antistatic agent layers 35 and 36 are set to 0.01 μm or more, an antistatic function can be easily exhibited. When the thicknesses of the antistatic agent layers 35 and 36 are set to 5 μm or less, an adhesion performance between the pressure-sensitive adhesive layer and the substrate can be improved.

A solution for forming an antistatic agent layer is applied to the substrate 31 and dried to form the antistatic agent layers 35 and 36. Various application methods can be adopted such as spin coating, spray coating, dip coating, screen printing, and wire bar coating.

### (Film for Rear Surface of Flip-Chip Semiconductor)

The film 2 for a rear surface of a semiconductor has a film form. The film 2 for a rear surface of a semiconductor is normally non-cured (including semi-cured) when it is in the form of a dicing tape integrated film for a rear surface of a semiconductor as a product, and the dicing tape integrated film for a rear surface of a semiconductor is bonded to a semiconductor wafer and then thermally cured (details will be described later).

The film for a rear surface of a semiconductor can be made of a resin composition, and can be composed of a resin composition containing a thermoplastic resin and a thermosetting resin. The film for a rear surface of a semiconductor may be composed of a thermoplastic resin composition in which a thermosetting resin is not contained, or may be composed of a thermosetting resin composition in which a thermoplastic resin is not contained.

Examples of the thermoplastic resin include a natural rubber, a butyl rubber, an isoprene rubber, a chloroprene rubber, an ethylene-vinyl acetate copolymer, an ethylene-acrylate copolymer, an ethylene-acrylic ester copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET (polyethylene terephthalate) and PBT (polybutylene terephthalate), a polyamideimide resin, and a fluororesin. The thermoplastic resins can be used alone or two types or more can be used together. Among these thermoplastic resins, an acrylic resin and a phenoxy resin are preferable, and a phenoxy resin is particularly preferable which can be formed into a film while maintaining a high tensile storage elastic modulus.

Examples of the phenoxy resin include, but are not particularly limited to, a resin obtained by the reaction of epichlorohydrin and a divalent phenolic compound, and an epoxy resin having a phenol component of a resin that is obtained by the reaction of a divalent epoxy-based compound and a divalent phenolic compound, etc. as a constituting unit. Examples of the phenoxy resin include phenoxy resins having at least one skeleton selected from bisphenol skeletons such as a bisphenol A type skeleton, a bisphenol F type skeleton, a bisphenol A/F mixed type skeleton, a bisphenol S type skeleton, a bisphenol M type skeleton, a bisphenol P type skeleton, a bisphenol A/P mixed type skeleton, and a bisphenol Z type skeleton; naphthalene skeletons; norbornene skeletons; fluorene skeletons; biphenyl skeletons; anthracene skeletons; novolak skeletons; pyrene skeletons; xanthene skeletons; adamantane skeletons; and dicyclopentadiene skeletons; and the like. A commercially available phenoxy resin can be also used. The phenoxy resin may be used alone or in combination of two or more kinds thereof.

The acrylic resin is not especially limited, and examples thereof include a polymer having one type or two types or more of acrylates or methacrylates having a linear or branched alkyl group having 30 or less carbon atoms (preferably 4 to 18 carbon atoms, further preferably 6 to 10 carbon atoms, and especially preferably 8 or 9 carbon atoms) as a component. That is, the acrylic resin of the first aspect of the present invention has a broad meaning and also includes a methacrylic resin. Examples of the alkyl group include a methyl group, an ethyl group, a propyl group, an isopropyl group, an n-butyl group, a t-butyl group, an isobutyl group, a pentyl group, an isopentyl group, a hexyl group, a heptyl group, a 2-ethylhexyl group, an octyl group, an isooctyl group, a nonyl group, an isononyl group, a decyl group, an isodecyl group, an undecyl group, a dodecyl group (a lauryl group), a tridecyl group, a tetradecyl group, a stearyl group, and an octadecyl group.

Other monomers that can form the above-described acrylic resin (monomers other than an alkylester of acrylic acid or methacrylic acid having an alkyl group having 30 or less carbon atoms) are not especially limited. Examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl) methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl(meth)acrylate, and (meth)acryloyloxynaphthalenesulfonic acid; and monomers which contain a phosphoric acid group, such as 2-hydroxyethylacryloyl phosphate. Among these, a carboxyl group-containing monomer is preferable from the viewpoint that the tensile storage modulus Ea of the die bond film can be set at a preferred value. (Meth)acrylate refers to an acrylate and/or a methacrylate, and every “(meth)” in the first aspect of the present invention has the same meaning.

Examples of the thermosetting resin include an epoxy resin, a phenol resin, an amino resin, an unsaturated polyester resin, a polyurethane resin, a silicone resin, and a thermosetting polyimide resin. The thermosetting resins can be used alone or two types or more can be used together. An epoxy resin having a small amount of ionic impurities that erode the semiconductor element is especially suitable as the thermosetting resin. Further, a phenol resin can be suitably used as a curing agent for the epoxy resin.

The epoxy resin is not especially limited, and examples thereof include bifunctional epoxy resins and polyfunctional epoxy resins such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a bisphenyl type epoxy resin, a naphthalene type epoxy resin, a fluorene type epoxy resin, a phenol novolak type epoxy resin, an ortho-cresol novolak type epoxy resin, a trishydroxyphenylmethane type epoxy resin, and a tetraphenylolethane type epoxy resin, a hydantoin type epoxy resin, a trisglycidylisocyanurate type epoxy resin, and a glycidylamine type epoxy resin.

Among the above-described epoxy resins, a novolak type epoxy resin, a biphenyl type epoxy resin, a trishydroxyphenylmethane type epoxy resin, and a tetraphenylolethane type epoxy resin are especially preferable. These epoxy resins are highly reactive with a phenol resin as a curing agent and are excellent in heat resistance.

The phenol resin acts as a curing agent for the epoxy resin, and examples thereof include novolak type phenol resins such as a phenol novolak resin, a phenol aralkyl resin, a cresol novolak resin, a tert-butylphenol novolak resin, and a nonylphenol novolak resin, a resol type phenol resin, and polyoxystyrenes such as polyparaoxystyrene. The phenol resins can be used alone or two types or more can be used together. Among these phenol resins, a phenol novolak resin and a phenol aralkyl resin are especially preferable because connection reliability of the semiconductor device can be improved.

The phenol resin is suitably compounded in the epoxy resin so that a hydroxyl group in the phenol resin to 1 equivalent of an epoxy group in the epoxy resin component becomes 0.5 to 2.0 equivalents. The ratio is more preferably 0.8 to 1.2 equivalents. When the compounding ratio goes out of this range, sufficient curing reaction does not proceed, and the characteristics of the epoxy resin cured substance easily deteriorate.

In the first aspect of the present invention, a thermal curing-accelerating catalyst of the epoxy resin and the phenol resin may be used. The thermal curing-accelerating catalyst is not particularly limited, and can be appropriately selected from known thermal curing-accelerating catalysts and used. The thermal curing-accelerating catalyst may be used alone or in combination of two or more kinds thereof. Examples of the thermal curing-accelerating catalyst include an amine-based curing-accelerating catalyst, a phosphorus-based curing-accelerating catalyst, an imidazole-based curing-accelerating catalyst, a boron-based curing-accelerating catalyst, and a phosphorus-boron-based curing-accelerating catalyst.

The amine-based curing-accelerating catalyst is not especially limited, and examples thereof include monoethanolamine trifluoroborate manufactured by Stella Chemifa Corporation and dicyandiamide manufactured by Nacalai Tesque, Inc.

The phosphorus-based curing-accelerating catalyst is not especially limited, and examples thereof include triorganophosphines such as triphenylphosphine, tributylphosphine, tri(p-methylphenyl)phosphine, tri(nonylphenyl)phosphine, and diphenyltolylphosphine; tetraphenylphosphonium bromide (trade name; TPP-PB); methyltriphenylphosphonium (trade name; TPP-MB); methyltriphenylphosphonium chloride (trade name; TPP-MC); methoxymethyltriphenylphosphonium (trade name; TPP-MOC); and benzyltriphenylphosphonium chloride (trade name; TPP-ZC) (all are manufactured by Hokko Chemical Industry Co., Ltd.). The triphenylphosphine-based compound preferably exhibits substantial insolubility to the epoxy resin. When it is insoluble to the epoxy resin, an excess progress of thermal curing can be suppressed. Examples of the thermosetting catalyst having a triphenylphosphine structure and substantially insoluble in an epoxy resin include methyltriphenylphosphonium (trade name; TPP-MB). “Insoluble” means that the thermosetting catalyst made of a triphenylphosphine-based compound is insoluble in a solvent made of an epoxy resin. In further detail, it means that no more than 10% by weight of the catalyst is soluble in the solvent at a temperature of 10 to 40° C.

Examples of the imidazole-based curing-accelerating catalyst include 2-methylimidazole (trade name; 2MZ), 2-undecylimidazole (trade name; C11-Z),2-heptadecylimidazole (tradename; C17Z),1,2-dimethylimidazole (tradename; 1.2DMZ), 2-ethyl-4-methylimidazole (trade name; 2E4MZ), 2-phenylimidazole (trade name; 2PZ), 2-phenyl-4-methylimidazole (trade name; 2P4MZ), 1-benzyl-2-methylimidazole (trade name; 1B2MZ), 1-benzyl-2-phenylimidazole (trade name; 1B2PZ), 1-cyanoethyl-2-methylimidazole (trade name; 2MZ-CN), 1-cyanoethyl-2-undecylimidazole (trade name; C11Z-CN), 1-cyanoethyl-2-phenylimidazolium trimellitate (trade name; 2PZCNS-PW), 2,4-diamino-6-[2′-methylimidazolyl-(1′)]-ethyl-s-triazine (trade name; 2MZ-A), 2,4-diamino-6-[2′-undecylimidazolyl-(1′)]-ethyl-s-triazine (trade name; C11Z-A), 2,4-diamino-6-[2′-ethyl-4′-methylimidazolyl-(1′)]-ethyl-s-triazine (trade name; 2E4MZ-A), 2,4-diamino-6-[2′-methylimidazolyl-(1′)]-ethyl-s-triazine isocyanuric acid adduct (trade name; 2MA-OK), 2-phenyl-4,5-dihydroxymethylimidazole (trade name; 2PHZ-PW), and 2-phenyl-4-methyl-5-hydroxymethylimidazole (trade name; 2P4 MHZ-PW) (all are manufactured by Shikoku Chemicals Corporation).

The boron-based curing-accelerating catalyst is not especially limited, and examples thereof include trichloroborane.

The phosphorus-boron-based curing-accelerating catalyst is not especially limited, and examples thereof include tetraphenylphosphonium tetraphenylborate (trade name; TPP-K), tetrtaphenylphosphoniumtetra-p-triborate (trade name; TPP-MK), benzyltriphenylphosphonium tetraphenylborate (trade name; TPP-ZK), and triphenylphosphine triphenylborane (trade name; TPP-S) (all are manufactured by Hokko Chemical Industry Co., Ltd.).

The weight percentage of the thermal curing-accelerating catalyst is preferably 0.01% by weight or more and 20% by weight or less to the entire weight of the thermosetting resin. When the weight percentage of the thermal curing-accelerating catalyst is 0.01% by weight or more, warping of a semiconductor element that is flip-chip bonded on an adherend can be effectively suppressed or prevented even when the semiconductor element is thin (for example, even when its thickness is 300 μm or less, and even more 200 μm or less). When the weight percentage of the thermal curing-accelerating catalyst is 20% by weight or less, the shrinkage of the film for a rear surface of a semiconductor does not become excessive, and the size of the film can be controlled to be appropriate. The lower limit of the weight percentage of the thermal curing-accelerating catalyst is preferably 0.03% by weight or more, and more preferably 0.05% by weight or more. The upper limit thereof is preferably 18% by weight or less, and more preferably 15% or less.

The film for a rear surface of a semiconductor is preferably made of a resin composition containing an epoxy resin and a phenol resin, and more preferably made of a resin composition containing an epoxy resin, a phenol resin, and a phenoxy resin.

It is important that the film 2 for a rear surface of a semiconductor has tackiness (adhesion) to the backside (the surface where a circuit is not formed) of a semiconductor wafer. The film 2 for a rear surface of a semiconductor can be formed of, for example, a resin composition containing an epoxy resin as the thermosetting resin. Because the film 2 for a rear surface of a semiconductor is crosslinked to some extent in advance, a polyfunctional compound that reacts with a functional group at the end of a molecular chain of the polymer is preferably added as a crosslinking agent at production. With this addition, adhering characteristics at high temperature can be improved and heat resistance can be improved.

The adhering strength (at 23° C., peeling angle of 180°, and peeling rate of 300 mm/minute) of the film for a rear surface of a semiconductor to a semiconductor wafer is preferably 1 N/10 mm width or more (for example, 1 N/10 mm width to 10 N/10 mm width), further preferably 2 N/10 mm width or more (for example, 2 N/10 width to 10 N/10 mm width), and particularly preferably 4 N/10 mm width or more (for example, 4 N/10 width to 10 N/10 mm width). This allows the film for a rear surface of a semiconductor to bond to a semiconductor wafer or a semiconductor element with excellent adhesion, and generation of floating or the like can be prevented. Further, generation of chip fly when dicing the semiconductor wafer can be also prevented. The adhering strength of the film for a rear surface of a semiconductor to a semiconductor wafer is a value that is measured as follows for example. That is, a pressure-sensitive adhesive tape (trade name “BT315” manufactured by Nitto Denko Corporation) is bonded to one surface of the film for a rear surface of a semiconductor to reinforce the rear surface. After that, a semiconductor wafer having a thickness of 0.6 mm is bonded to the front surface of the film for a rear surface of a semiconductor having a length of 150 mm and a width of 10 mm, whose rear surface is reinforced, with a heat laminating method at 50° C. by moving a roller of 2 kg back and forth once. After that, it is allowed to stand at rest on a hot plate (at 50° C.) for 2 minutes, and then allowed to stand at rest at normal temperature (about 23° C.) for 20 minutes. After standing at rest, the film for a rear surface of a semiconductor whose rear surface is reinforced is peeled off at a temperature of 23° C. under conditions of a peeling angle of 180° and a tensile rate of 300 mm/minute using a release tester (trade name “AUTOGRAPH AGS-J” manufactured by SHIMADZU CORPORATION). The adhering strength is a value (N/10 mm width) measured by peeling off the film for a rear surface of a semiconductor at the interface with the semiconductor wafer.

The crosslinking agent is not especially limited, and a known crosslinking agent can be used. Specific examples thereof include an isocyanate crosslinking agent, an epoxy crosslinking agent, a melamine crosslinking agent, a peroxide crosslinking agent, a urea crosslinking agent, a metal alkoxide crosslinking agent, a metal chelate crosslinking agent, a metal salt crosslinking agent, a carbodiimide crosslinking agent, an oxazoline crosslinking agent, an aziridine crosslinking agent, and an amine crosslinking agent. An isocyanate crosslinking agent and an epoxy crosslinking agent are preferable. The crosslinking agents can be used alone or two type or more can be used together.

Examples of the isocyanate crosslinking agent include lower aliphatic polyisocyanates such as 1,2-ethylene diisocyanate, 1,4-butylene isocyanate, and 1,6-hexamethylene diisocyanate; alicyclicpolyisocyanates such as cyclopentylene diisocyanate, cyclohexylene diisocyanate, isophorone diisocyanate, hydrogenated tolylene diisocyanate, and hydrogenated xylene diisocyanate; and aromatic polyisocyanates such as 2,4-tolylene diisocyanate, 2,6-tolylene diisocyanate, 4,4′-diphenylmethanediisocyanate, and xylylenediisiocyanate. A trimethylolpropane/tolylene diisocyanate trimer adduct (tradename: Coronate L manufactured by Nippon Polyurethane Industry Co., Ltd.) and a trimethylolpropane/hexamethylene diisocyanate trimer adduct (tradename: Coronate HL manufactured by Nippon Polyurethane Industry Co., Ltd.) can also be used. Examples of the epoxy crosslinking agent include N,N,N′,N′-tetraglycidyl-m-xylenediamine, diglycidylaniline, 1,3-bis(N,N-glycidylaminomethyl)cyclohexane, 1,6-hexanediol diglycidylether, neopentylglycol diglycidylether, ethyleneglycol diglycidylether, propyleneglycol diglycidylether, polyethyleneglycol diglycidylether, polypropyleneglycol diglycidylether, sorbitol polyglycidylether, glycerol polyglycidylether, pentaerythritol polyglycidylether, polyglyserol polyglycidylether, sorbitan polyglycidylether, trimethylolpropane polyglycidylether, diglycidyl adipate, diglycidyl o-phthalate, triglycidyl-tris(2-hydroxyethyl)isocyanurate, resorcin diglycidylether, bisphenol-s-diglycidyl ether, and an epoxy resin having two or more epoxy groups in the molecule.

The used amount of the crosslinking agent is not especially limited, and can be appropriately selected according to the level of crosslinking. Specifically, the used amount of the crosslinking agent is normally preferably 7 parts by weight or less (0.05 to 7 parts by weight, for example) to 100 parts by weight of a polymer component (especially, a polymer having a functional group at the end of the molecular chain) for example. When the used amount of the crosslinking agent is more than 7 parts by weight to 100 parts by weight of the polymer component, it is not preferable because the adhering strength decreases. From the viewpoint of improving cohesive strength, the used amount of the crosslinking agent is preferably 0.05 parts by weight or more to 100 parts by weight of the polymer component.

In the first aspect of the present invention, it is possible to perform a crosslinking treatment by irradiation with an electron beam, an ultraviolet ray, or the like in place of using the crosslinking agent or together with a crosslinking agent.

The film for a rear surface of a semiconductor is preferably colored. With this configuration, the film for a rear surface of a semiconductor can exhibit an excellent marking property and an excellent appearance, and a semiconductor device can be obtained having an appearance with added value. Because the colored film for a rear surface of a semiconductor has an excellent marking property, various information such as character information and pattern information can be given to a semiconductor device or the surface where a circuit is not formed of the semiconductor device in which the semiconductor element is marked through the film for a rear surface of a semiconductor using various marking methods such as a printing method and a laser marking method. Especially, the information such as character information and pattern information that is given by marking can be recognized visually with excellent visibility by controlling the color. Because the film for a rear surface of a semiconductor is colored, the dicing tape and the film for a rear surface of a semiconductor can be easily distinguished, and workability can be improved. It is possible to color-code the semiconductor device by product, for example. When the film for a rear surface of a semiconductor is colored (when it is not colorless or transparent), the color is not especially limited. However, the color is preferably a dark color such as black, blue, or red, and black is especially preferable.

In this embodiment, the dark color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of a* and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

In this embodiment, L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I'Eclairage (CIE) in 1976, and means a color space that is called a CIE1976 (L*a*b*) color system. The L*a*b* color system is provided in JIS Z 8729 in the Japanese Industrial Standards.

When coloring the film for a rear surface of a semiconductor, a coloring material (coloring agent) can be used according to the objective color. Various dark color materials such as black color materials, blue color materials, and red color materials can be suitably used, and especially the black color materials are suitable. The color materials may be any of pigments, dyes, and the like. The color materials can be used alone or two types or more can be used together. Any dyes such as acid dyes, reactive dyes, direct dyes, dispersive dyes, and cationic dyes can be used. The pigments are also not especially limited in the form, and may be appropriately selected from known pigments.

When dyes are used as the color materials, the film for a rear surface of a semiconductor (consequently a dicing tape integrated film for a rear surface of a semiconductor) having uniform or almost uniform coloring concentration can be easily manufactured because the dyes disperse uniformly or almost uniformly due to dissolution in the film for a rear surface of a semiconductor. Because of that, when the dyes are used as the color materials, the coloring concentration of the film for a rear surface of a semiconductor in the dicing tape integrated film for a rear surface of a semiconductor can be made uniform or almost uniform, and the marking property and the appearance can be improved.

The black color material is not especially limited, and can be appropriately selected from inorganic black pigments and black dyes, for example. The black color material may be a color material mixture in which a cyan color material (blue-green color material), a magenta color material (red-purple color material), and a yellow color material are mixed together. The black color materials can be used alone or two types or more can be used together. The black color materials can be used also with other color materials other than black.

Specific examples of the black color materials include carbon black such as furnace black, channel black, acetylene black, thermal black, and lamp black, graphite (black lead), copper oxide, manganese dioxide, azo pigments such as azomethine azo black, aniline black, perylene black, titaniumblack, cyanine black, activated carbon, ferrite such as nonmagnetic ferrite and magnetic ferrite, magnetite, chromium oxide, iron oxide, molybdenum disulfide, chromium complex, complex oxide black, and anthraquinone organic black.

In the first aspect of the present invention, black dyes such as C. I. solvent black 3, 7, 22, 27, 29, 34, 43, and 70, C. I. direct black 17, 19, 22, 32, 38, 51, and 71, C. I. acid black 1, 2, 24, 26, 31, 48, 52, 107, 109, 110, 119, and 154, and C. I. disperse black 1, 3, 10, and 24; and black pigments such as C. I. pigment black 1 and 7 can be used as the black color material.

Examples of such black color materials that are available on the market include Oil Black BY, Oil Black BS, Oil Black HBB, Oil Black 803, Oil Black 860, Oil Black 5970, Oil Black 5906, and Oil Black 5905 manufactured by Orient Chemical Industries Co., Ltd.

Examples of color materials other than the black color materials include a cyan color material, a magenta color material, and a yellow color material. Examples of the cyan color material include cyan dyes such as C. I. solvent blue 25, 36, 60, 70, 93, and 95; and C. I. acid blue 6 and 45; and cyan pigments such as C. I. pigment blue 1, 2, 3, 15, 15:1, 15:2, 15:3, 15:4, 15:5, 15:6, 16, 17, 17:1, 18, 22, 25, 56, 60, 63, 65, and 66; C. I. vat blue 4 and 60; and C. I. pigment green 7.

Examples of the magenta color material include magenta dyes such as C. I. solvent red 1, 3, 8, 23, 24, 25, 27, 30, 49, 52, 58, 63, 81, 82, 83, 84, 100, 109, 111, 121, and 122; C. I. disperse red 9; C. I. solvent violet 8, 13, 14, 21, and 27; C. I. disperse violet 1; C. I. basic red 1, 2, 9, 12, 13, 14, 15, 17, 18, 22, 23, 24, 27, 29, 32, 34, 35, 36, 37, 38, 39, and 40; and C. I. basic violet 1, 3, 7, 10, 14, 15, 21, 25, 26, 27, and 28.

Examples of the magenta color material include magenta pigments such as C. I. pigment red 1, 2, 3, 4, 5, 6, 7, 8, 9, 10, 11, 12, 13, 14, 15, 16, 17, 18, 19, 21, 22, 23, 30, 31, 32, 37, 38, 39, 40, 41, 42, 48:1, 48:2, 48:3, 48:4, 49, 49:1, 50, 51, 52, 52:2, 53:1, 54, 55, 56, 57:1, 58, 60, 60:1, 63, 63:1, 63:2, 64, 64:1, 67, 68, 81, 83, 87, 88, 89, 90, 92, 101, 104, 105, 106, 108, 112, 114, 122, 123, 139, 144, 146, 147, 149, 150, 151, 163, 166, 168, 170, 171, 172, 175, 176, 177, 178, 179, 184, 185, 187, 190, 193, 202, 206, 207, 209, 219, 222, 224, 238, and 245; C. I. pigment violet 3, 9, 19, 23, 31, 32, 33, 36, 38, 43, and 50; and C. I. vat red 1, 2, 10, 13, 15, 23, 29, and 35.

Examples of the yellow color material include yellow dyes such as C. I. solvent yellow 19, 44, 77, 79, 81, 82, 93, 98, 103, 104, 112, and 162; and yellow pigments such as C. I. pigment orange 31 and 43, C. I. pigment yellow 1, 2, 3, 4, 5, 6, 7, 10, 11, 12, 13, 14, 15, 16, 17, 23, 24, 34, 35, 37, 42, 53, 55, 65, 73, 74, 75, 81, 83, 93, 94, 95, 97, 98, 100, 101, 104, 108, 109, 110, 113, 114, 116, 117, 120, 128, 129, 133, 138, 139, 147, 150, 151, 153, 154, 155, 156, 167, 172, 173, 180, 185, and 195, and C. I. vat yellow 1, 3, and 20.

Various color materials such as cyan color materials, magenta color materials, and yellow color materials can be used alone or two types or more can be used together. When two types or more of various color materials such as cyan color materials, magenta color materials, and yellow color materials are used, the mixing ratio or the compounding ratio of these color materials is not especially limited, and can be appropriately selected according to the types of each color material and the intended color.

When coloring the film 2 for a rear surface of a semiconductor, the colored state of the layers is not especially limited. For example, the film for a rear surface of a semiconductor may be a single layered film in which the coloring agent is added. They may also be a laminated film in which at least a resin layer formed at least of a thermosetting resin and a coloring agent layer are laminated. When the film 2 for a rear surface of a semiconductor is in the form of a laminated film of the resin layer and the coloring agent layer, the film 2 for a rear surface of a semiconductor preferably has a laminated state of a resin layer/a coloring agent layer/a resin layer. In this case, the two resin layers on both sides of the coloring agent layer may be resin layers having the same composition or may be resin layers having different compositions.

Other additives can be appropriately compounded in the film 2 for a rear surface of a semiconductor as necessary. Examples of the other additives include a filler, a flame retardant, a silane coupling agent, an ion trapping agent, an extender, an anti-aging agent, an antioxidant, and a surfactant.

The filler may be any of an inorganic filler and an organic filler. However, an inorganic filler is preferable. By adding a filler such as an inorganic filler, electric conductivity can be given to the film for a rear surface of a semiconductor, heat conductivity can be improved, and the elastic modulus can be adjusted. The film 2 for a rear surface of a semiconductor may be electrically conductive or non-conductive. Examples of the inorganic filler include ceramics such as silica, clay, gypsum, calcium carbonate, barium sulfate, alumina, beryllium oxide, silicon carbide, and silicon nitride, metals such as aluminum, copper, silver, gold, nickel, chromium, lead, tin, zinc, palladium, and solder, alloys, and various inorganic powders consisting of carbon. The fillers may be used alone or two types or more can be used together. Among these, silica, especially molten silica is preferable. The average particle size of the inorganic filler is preferably in a range of 0.1 to 80 μm. The average particle size of the inorganic filler can be measured with a laser diffraction type particle size distribution device, for example.

The compounding amount of the filler (especially, the inorganic filler) is preferably 80 parts by weight or less (0 to 80 parts by weight), and especially preferably 0 to 70 parts by weight to 100 parts by weight of the organic resin component.

Examples of the flame retardant include antimony trioxide, antimony pentoxide, and a brominated epoxy resin. These can be used alone or two types or more can be used together. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These compounds can be used alone or two types or more can be used together. Examples of the ion trap agent include hydrotalcites and bismuth hydroxide. These can be used alone or two types or more can be used together.

For example, the film 2 for a rear surface of a semiconductor can be formed using a common method of mixing a thermosetting resin such as an epoxy resin, and if necessary, a thermoplastic resin such as a phenoxy resin or an acrylic resin, a solvent, other additives, or the like to prepare a resin composition, and forming the resultant into a film-formed layer. Specifically, a film layer (an adhesive layer) as the film for a rear surface of a semiconductor can be formed by a method of applying the resin composition onto the pressure-sensitive adhesive layer 32 of the dicing tape, a method of applying the resin composition onto an appropriate separator such as release paper to form a resin layer (or an adhesive layer) and transcribing (transferring) the resin layer onto the pressure-sensitive adhesive layer 32, or the like. The resin composition may be a solution or a dispersion liquid.

When the film 2 for a rear surface of a semiconductor is formed of a resin composition containing a thermosetting resin such as an epoxy resin, the thermosetting resin in the film for a rear surface of a semiconductor is uncured or is partially cured at the stage before application to a semiconductor wafer. In this case, the thermosetting resin in the film for a rear surface of a semiconductor is completely cured or almost completely cured after application to a semiconductor wafer (normally when curing a sealing material in a flip-chip bonding step).

Even if the film for a rear surface of a semiconductor contains the thermosetting resin, since the thermosetting resin is uncured or is partially cured, the gel fraction of the film for the backside of a semiconductor is not especially limited. The gel fraction can be appropriately selected from a range of 50% by weight or less (0 to 50% by weight), preferably 30% by weight or less (0 to 30% by weight), and especially preferably 10% by weight or less (0 to 10% by weight). The gel fraction of the film for a rear surface of a semiconductor can be measured by the following method.

### <Method of Measuring Gel Fraction>

About 0.1 g of a sample (sample weight) is precisely weighed from the film for a rear surface of a semiconductor, the sample is wrapped with a mesh sheet, and then the sample is immersed in about 50 ml of toluene at room temperature for a week. After that, the portion insoluble in the solvent (content of the mesh sheet) is taken out of toluene and dried at 130° C. for about 2 hours, and after drying, the portion insoluble in the solvent is weighed (weight after immersion and drying), and the gel fraction (% by weight) is calculated from the following formula (a).

Gel fraction(% by weight)=[(Weight after immersion and drying)/(Sample weight)]×100 (a)

The gel fraction of the film for a rear surface of a semiconductor can be controlled by the type and the content of the resin component, the type and the content of the crosslinking agent, the heating temperature, the heating time, and the like.

When the film for a rear surface of a semiconductor in the first aspect of the present invention is a film that is formed with a resin composition containing a thermosetting resin such as an epoxy resin, adhesion to a semiconductor wafer can be exhibited effectively.

Because cutting water is used in the dicing step of the semiconductor wafer, the film for a rear surface of a semiconductor may absorb moisture and the water content may exceed the normal value. When flip-chip bonding is performed with such a high water content, water vapor is accumulated in the boundary between the film 2 for a rear surface of a semiconductor and a semiconductor wafer or a processed body thereof (a semiconductor), and floating may occur. Therefore, to avoid such a problem, the film for a rear surface of a semiconductor is made to have a configuration in which a core material having high moisture permeability is provided on both surfaces thereof to diffuse water vapor. From such a viewpoint, a multilayered structure in which film 2 for a rear surface of a semiconductor are formed on one surface or both surfaces of the core material may be used as the film for a rear surface of a semiconductor. Examples of the core material include a film such as a polyimide film, a polyester film, a polyethylene terephthalate film, a polyethylene naphthalate film, or a polycarbonate film, a resin substrate reinforced by a glass fiber or a plastic nonwoven fiber, a silicon substrate, or a glass substrate.

The thickness (total thickness in the case of a laminated film) of the film 2 for a rear surface of a semiconductor is not especially limited. However, the thickness can be appropriately selected from a range of about 2 to 200 μm. The thickness is preferably about 4 to 160 μm, more preferably about 6 to 100 μm, and especially preferably about 10 to 80 μm.

The tensile storage modulus at 23° C. of the uncured film 2 for a rear surface of a semiconductor is preferably 1 GPa or more (1 to 50 GPa, for example), more preferably 2 GPa or more, and especially preferably 3 GPa or more. When the tensile storage modulus is 1 GPa or more, adhesion of the film for a rear surface of a semiconductor to a support can be effectively suppressed or prevented when a semiconductor element is peeled from the pressure-sensitive adhesive layer 32 of a dicing tape together with the film 2 for a rear surface of a semiconductor and the film 2 for a rear surface of a semiconductor mounted on the support are transported. Examples of the support include a top tape and a bottom tape of a carrier tape. When the film 2 for a rear surface of a semiconductor is formed of a resin composition containing a thermosetting resin, the thermosetting resin is normally uncured or partially cured as described above. Therefore, the elastic modulus of the film for a rear surface of a semiconductor at 23° C. is normally the elastic modulus of the uncured or partially cured thermosetting resin at 23° C.

The film 2 for a rear surface of a semiconductor may be of a single layer or may be a laminated film in which a plurality of layers are laminated. However, when the film for a rear surface of a semiconductor is a laminated film, the tensile storage modulus of the uncured film at 23° C. may be 1 GPa or more (1 to 50 GPa, for example) as a whole laminated film. The tensile storage modulus (23° C.) in the uncured portion of the film for a rear surface of a semiconductor can be controlled by the type and the content of the resin component (a thermoplastic resin and a thermosetting resin), the type and the content of the filler such as a silica filler, and the like. As for the case where the film 2 for a rear surface of a semiconductor is a laminated film in which a plurality of layers are laminated (when the film for a rear surface of a semiconductor has a lamination form), examples of the lamination form include a lamination form consisting of a wafer adhesive layer and a laser marking layer. Other layers such as an intermediate layer, a light beam shielding layer, a reinforcing layer, a coloring agent layer, a base layer, an electromagnetic wave shielding layer, a heat conducting layer, and a pressure-sensitive adhesive layer may be provided between the wafer adhesive layer and the laser marking layer. The wafer adhesive layer is a layer having excellent adhesion (tackiness) to a wafer and contacting with the backside of the wafer. The laser marking layer is a layer having an excellent laser marking property and is used to perform laser marking on the backside of a semiconductor element.

The uncured film 2 for a rear surface of a semiconductor was produced without laminating the films on the dicing tape 3, and the tensile storage modulus was measured using a dynamic viscoelasticity measurement apparatus (Solid Analyzer RS A2) manufactured by Rheometric Scientific FE, Ltd. in tensile mode, sample width 10 mm, sample length 22.5 mm, sample thickness 0.2 mm, frequency 1 Hz, temperature rise rate 10° C./min, under a nitrogen atmosphere, and at a prescribed temperature (23° C.).

At least one of the surfaces of the film 2 for a rear surface of a semiconductor is preferably protected by a separator (a release liner, not shown in the drawings). In a case of a dicing tape integrated film 1 for the backside of a semiconductor, the separator may be provided only on one surface of the film for a rear surface of a semiconductor. On the other hand, in the case of a film for a rear surface of a semiconductor that is not integrated with the dicing tape, the separator may be provided on one surface or both surfaces of the film for a rear surface of a semiconductor. The separator has a function of protecting the film for a rear surface of a semiconductor as a protective material until the film is used. In the case of the dicing tape integrated film 1 for the backside of a semiconductor, the separator can be further used as a support base when transferring the film 2 for a rear surface of a semiconductor to the pressure-sensitive adhesive layer 32 on the substrate of the dicing tape. The separator is peeled when pasting the semiconductor wafer onto the film for a rear surface of a semiconductor. Examples of the separator include polyethylene, polypropylene, a plastic film such as polyethylene terephthalate whose surface is coated with a release agent such as a fluorine release agent or a long chain alkylacrylate release agent, and paper. The separator can be formed by a conventionally known method. The thickness of the separator is also not especially limited.

The light transmittance (visible light transmittance) of visible light (having a wavelength of 400 to 800 nm) in the film 2 for a rear surface of a semiconductor is not especially limited, and is preferably in a range of 20% or less (0 to 20%), more preferably 10% or less (0 to 10%), and especially preferably 5% or less (0 to 5%). When the visible light transmittance of the film 2 for a rear surface of a semiconductor is larger than 20%, there is a fear that a bad influence may be given to the semiconductor element when the light beam passes. The visible light transmittance (%) can be controlled by the type and the content of the resin component of the film 2 for a rear surface of a semiconductor, the type and the content of the coloring agent such as a pigment or a dye, the content of the inorganic filler, and the like.

The visible light transmittance (%) of the film 2 for a rear surface of a semiconductor can be measured as follows. That is, the film 2 for a rear surface of a semiconductor having a thickness (average thickness) of 20 μm is produced. The film 2 for a rear surface of a semiconductor is then irradiated with visible light having a wavelength of 400 to 800 nm (a visible light generator “Absorption Spectro Photometer” manufactured by Shimadzu Corporation) at a prescribed intensity, and the intensity of the transmitted visible light beam is measured.

The visible light transmittance can be obtained from a change of the intensity before and after the visible light beam transmits through the film 2 for a rear surface of a semiconductor. It is also possible to obtain the visible light transmittance (%; wavelength: 400 to 800 nm) of the film 2 for a rear surface of a semiconductor having a thickness of 20 μm from the visible light transmittance (%; wavelength: 400 to 800 nm) of the film 2 for a rear surface of a semiconductor whose thickness is not 20 μm. The visible light transmittance (%) of the film 2 for a rear surface of a semiconductor having a thickness of 20 μm is obtained in the first aspect of the present invention. However, the thickness of the film for a rear surface of a semiconductor according to the first aspect of the present invention is not limited to 20 μm.

The coefficient of moisture absorption of the film 2 for a rear surface of a semiconductor is preferably low. Specifically, the coefficient of moisture absorption is preferably 1% by weight or less, and more preferably 0.8% by weight or less. By making the coefficient of moisture absorption 1% by weight or less, the laser marking property can be improved. Further, generation of voids between the film 2 for a rear surface of a semiconductor and the semiconductor element can be suppressed or prevented in a reflow step, for example. The coefficient of moisture absorption is a value calculated from the weight change before and after the film 2 for a rear surface of a semiconductor are left under an atmosphere of a temperature of 85° C. and a relative humidity of 85% RH for 168 hours. When the film 2 for a rear surface of a semiconductor are formed of a resin composition containing a thermosetting resin, the coefficient of moisture absorption is a value obtained the films for the backside of a semiconductor after thermal curing are left under an atmosphere of a temperature of 85° C. and a relative humidity of 85% RH for 168 hours. The coefficient of moisture absorption can be adjusted by changing the added amount of the inorganic filler, for example.

The ratio of the volatile component of the film 2 for a rear surface of a semiconductor is preferably small. Specifically, the weight decrease rate (ratio of the weight decrease amount) of the film 2 for a rear surface of a semiconductor after a heat treatment is preferably 1% by weight or less, and more preferably 0.8% by weight or less. The condition of the heating treatment is a heating temperature of 250° C. and a heating time of 1 hour, for example. By making the weight decrease rate 1% by weight or less, the laser marking property can be improved. The generation of cracks in the flip-chip type semiconductor device can be suppressed or prevented in a reflow step, for example. The weight decrease rate can be adjusted by adding an inorganic substance that can decrease the generation of cracks during a lead free solder reflow, for example. When the film 2 for a rear surface of a semiconductor is formed with a resin composition containing a thermosetting resin, the weight decrease rate means a value obtained when the film for a rear surface of a semiconductor after thermal curing is heated under conditions of a heating temperature of 250° C. and a heating time of 1 hour.

(Dicing tape)

The dicing tape 3 as a configuration in which the pressure-sensitive adhesive 32 is formed on the substrate 31.

As described above, the dicing tape 3 may have a configuration in which the substrate 31 and the pressure-sensitive adhesive layer 32 are laminated. The substrate (support substrate) can be used as a support body of the pressure-sensitive adhesive layer, and the like. The substrate 31 preferably has radiation transparency. Examples of the substrate 31 include appropriate thin materials including paper substrates such as paper; fiber substrates such as cloth, unwoven cloth, felt, and net; metal substrates such as a metal foil and a metal plate; plastic substrates such as a plastic film and sheet; rubber substrates such as a rubber sheet; foams such as a foamed sheet, and laminated bodies of these (especially laminated bodies of a plastic substrate and other substrates and laminated bodies of plastic films or sheets). In the first aspect of the present invention, a plastic substrate such as a plastic film or sheet can be preferably used as the substrate. Examples of the material of such a plastic substrate include olefin resins such as polyethylene (PE), polypropylene (PP), and an ethylene-propylene copolymer; copolymers having ethylene as a monomer component such as a ethylene vinyl acetate copolymer (EVA), an ionomer resin, a ethylene-(meth)acrylate copolymer, and an ethylene-(meth)acrylate (random, alternating) copolymer; polyesters such as polyethylene terephthalate (PET), polyethylene naphthalate (PEN), and polybutylene terephthalate (PBT); an acrylic resin; polyvinyl chloride (PVC); polyurethane; polycarbonate; polyphenylene sulfide (PPS); amide resins such as polyamide (nylon) and fully aromatic polyamide (aramid); polyether ether ketone (PEEK); polyimide; polyetherimide; polyvinylidene chloride; ABS (acrylonitrile-butadiene-styrene copolymer); a cellulose resin; a silicone resin; and a fluororesin.

Further, the material of the substrate 31 includes a polymer such as a cross-linked body of the above resins. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 32 and the film 2 for a rear surface of a semiconductor are reduced by thermally shrinking the substrate 31 after dicing, and the recovery of the semiconductor elements can be facilitated.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the substrate 31 in order to improve adhesiveness, holding properties, etc. with the adjacent layer.

The same type or different types can be appropriately selected and used as the substrate 31, and several types can be blended and used as necessary. A vapor deposited layer of a conductive substance having a thickness of about 30 to 500 Å consisting of metals, alloys, and oxides of these can be provided on the substrate 31 to give an antistatic function to the substrate 31. The substrate 31 may be a single layer or a multilayer consisting of two types or more layers.

The thickness of the substrate 31 (total thickness in the case of a laminated body) is not especially limited, and can be appropriately selected according to the strength, flexibility, purpose of use, and the like. For example, the thickness is generally 1000 μm or less (1 to 1000 μm, for example), preferably 10 to 500 μm, more preferably 20 to 300 μm, and especially preferably about 30 to 200 μm. However, the thickness is not limited to these ranges.

The substrate 31 may contain various additives such as a coloring agent, a filler, a plasticizer, an anti-aging agent, an antioxidant, a surfactant, and a flame retardant as long as the effects of the first aspect of the present invention are not deteriorated.

The pressure-sensitive adhesive layer 32 is formed with a pressure-sensitive adhesive, and has adherability. The pressure-sensitive adhesive is not especially limited, and can be appropriately selected among known pressure-sensitive adhesives. Specifically, known pressure-sensitive adhesives (refer to Japanese Patent Application Laid-Open Nos. 56-61468, 61-174857, 63-17981, and 56-13040, for example) such as a pressure-sensitive adhesive having the above-described characteristics can be appropriately selected from an acrylic pressure-sensitive adhesive, a rubber pressure-sensitive adhesive, a vinylalkylether pressure-sensitive adhesive, a silicone pressure-sensitive adhesive, a polyester pressure-sensitive adhesive, a polyamide pressure-sensitive adhesive, a urethane pressure-sensitive adhesive, a fluorine pressure-sensitive adhesive, a styrene-diene block copolymer pressure-sensitive adhesive, and a creep property improved pressure-sensitive adhesive in which a hot-melt resin having a melting point of about 200° C. or less is compounded in these pressure-sensitive adhesives. A radiation curing type pressure-sensitive adhesive (or an energy ray curing type pressure-sensitive adhesive) and a thermally expandable pressure-sensitive adhesive can also be used as the pressure-sensitive adhesive. The pressure-sensitive adhesives can be used alone or two types or more can be used together.

An acrylic pressure-sensitive adhesive and a rubber pressure-sensitive adhesive can be suitably used as the pressure-sensitive adhesive, and especially an acrylic pressure-sensitive adhesive is suitable. An example of the acrylic pressure-sensitive adhesive is an acrylic pressure-sensitive adhesive having an acrylic polymer, in which one type or two types or more of alkyl(meth)acrylates are used as a monomer component, as a base polymer.

Examples of alkyl(meth)acrylates in the acrylic pressure-sensitive adhesive include methyl(meth)acrylate, ethyl(meth)acrylate, propyl(meth)acrylate, isopropyl(meth)acrylate,butyl(meth)acrylate,isobutyl(meth)acrylate, s-butyl(meth)acrylate, t-butyl(meth)acrylate, pentyl(meth)acrylate, hexyl(meth)acrylate, heptyl(meth)acrylate, octyl(meth)acrylate, 2-ethylhexyl(meth)acrylate, isooctyl(meth)acrylate, nonyl(meth)acrylate, isononyl(meth)acrylate, decyl(meth)acrylate, isodecyl(meth)acrylate, undecyl(met) acrylate, dodecyl(meth)acrylate, tridecyl(meth)acrylate, tetradecyl(meth)acrylate, pentadecyl(meth)acrylate, hexadecyl(meth)acrylate, heptadecyl(meth)acrylate, octadecyl(meth)acrylate, nonadecyl(meth)acrylate, and eicosyl(meth)acrylate. Alkyl(meth)acrylates having an alkyl group of 4 to 18 carbon atoms is suitable. The alkyl group of alkyl(meth)acrylates may be any of linear or branched chain.

The acrylic polymer may contain units that correspond to other monomer components that is copolymerizable with alkyl(meth)acrylates described above (copolymerizable monomer component) for reforming cohesive strength, heat resistance, and crosslinking property, as necessary. Examples of such copolymerizable monomer components include carboxyl group-containing monomers such as (meth)acrylic acid (acrylic acid, methacrylic acid), carboxyethyl acrylate, carboxypentyl acrylate, itaconic acid, maleic acid, fumaric acid, and crotonic acid; acid anhydride group-containing monomers such as maleic anhydride and itaconic anhydride; hydroxyl group-containing monomers such as hydroxyethyl(meth)acrylate, hydroxypropyl(meth)acrylate, hydroxybutyl(meth)acrylate, hydroxyhexyl(meth)acrylate, hydroxyoctyl(meth)acrylate, hydroxydecyl(meth)acrylate, hydroxylauryl(meth)acrylate, and (4-hydroxymethylcyclohexyl)methyl methacrylate; sulfonate group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphate group-containing monomers such as 2-hydroxyethylacryloylphosphate; (N-substituted) amide monomers such as (meth)acrylamide, N,N-dimethyl(meth)acrylamide, N-butyl(meth)acrylamide, N-methylol(meth)acrylamide, and N-methylolpropane(meth)acrylamide; aminoalkyl(meth)acrylate monomers such as aminoethyl(meth)acrylate, N,N-dimethlaminoethyl(meth)acrylate, and t-butylaminoethyl(meth)acrylate; alkoxyalkyl(meth)acrylate monomers such as methoxyethyl(meth)acrylate and ethoxyethyl(meth)acrylate; cyanoacrylate monomers such as acrylonitrile and methacrylonitrile; epoxy group-containing acrylic monomers such as glycidyl(meth)acrylate; styrene monomers such as styrene and α-methylstyrene; vinylester monomers such as vinyl acetate and vinyl propionate; olefin monomers such as isoprene, butadiene, and isobutylene; vinylether monomers such as vinylether; nitrogen-containing monomers such as N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, N-vinylcarboxylic acid amides, and N-vinylcaprolactam; maleimide monomers such as N-cyclohexylmaleimide, N-isopropylmaleimide, N-laurylmaleimide, and N-phenylmaleimide; itaconimide monomers such as N-methylitaconimide, N-ethylitaconimide, N-butylitaconimide, N-octylitaconimide, N-2-ethylhexylitaconimide, N-cyclohexylitaconimide, and N-laurylitaconimide; succinimide monomers such as N-(meth)acryloyloxymethylene succinimide, N-(meth)acryloyl-6-oxyhexamethylene succinimide, and N-(meth)acryloyl-8-oxyoctamethylene succinimide; glycol acrylester monomers such as polyethylene glycol(meth)acrylate, polypropylene glycol(meth)acrylate, metoxyethylene glycol(meth)acrylate, andmetoxypolypropylene glycol(meth)acrylate; acrylate monomers having a heterocyclic ring, a halogen atom, a silicon atom, and the like such as tetrahydrofurfuryl(meth)acrylate, fluorine(meth)acrylate, and silicone(meth)acrylate; and polyfunctional monomers such as hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylolpropane tri(meth)acrylate, pentaerythritol tri(meth)acrylate, dipentaerythritol hexa(meth)acrylate, epoxyacrylate, polyesteracrylate, urethaneacrylate, divinylbenzene, butyl di(meth)acrylate, and hexyl di(meth)acrylate. One type or two types or more of these copolymerizable monomer components can be used.

When a radiation curing type pressure-sensitive adhesive (or an energy ray curing type pressure-sensitive adhesive) is used as the pressure-sensitive adhesive, examples of the radiation curing type pressure-sensitive adhesive (composition) include an internal radiation curing type pressure-sensitive adhesive having a polymer with a radical reactive carbon-carbon double bond in the polymer side chain, the main chain, or the ends of the main chain as a base polymer and a radiation curing type pressure-sensitive adhesive in which ultraviolet-ray curing-type monomer component and oligomer component are compounded in the pressure-sensitive adhesive. When a thermally expandable pressure-sensitive adhesive is used as the pressure-sensitive adhesive, examples thereof include a thermally expandable pressure-sensitive adhesive containing a pressure-sensitive adhesive and a foaming agent (especially, a thermally expandable microsphere).

The pressure-sensitive adhesive layer 32 of the first aspect of the present invention may contain various additives such as a tackifier, a coloring agent, a thickener, an extender, a filler, a plasticizer, an anti-aging agent, an antioxidant, a surfactant, and a crosslinking agent as long as the effects of the first aspect of the present invention are not deteriorated.

The crosslinking agent is not especially limited, and known crosslinking agents can be used. Specific examples of the crosslinking agent include an isocyanate crosslinking agent, an epoxy crosslinking agent, a melamine crosslinking agent, a peroxide crosslinking agent, a urea crosslinking agent, a metal alkoxide crosslinking agent, a metal chelate crosslinking agent, a metal salt crosslinking agent, a carbodiimide crosslinking agent, an oxazoline crosslinking agent, an aziridine crosslinking agent, and an amine crosslinking agent, and an isocyanate crosslinking agent and an epoxy crosslinking agent are preferable. The crosslinking agents can be used alone or two types or more can be used together. The used amount of the crosslinking agent is not especially limited.

Examples of the isocyanate crosslinking agent include lower aliphatic polyisocyanates such as 1,2-ethylene diisocyanate, 1,4-butylenediisocyanate, and 1,6-hexamethylene diisocyanate; alicyclicpolyisocyanates such as cyclopentylene diisocyanate, cyclohexylene diisocyanate, isophorone diisocyanate, hydrogenated tolylene diisocyanate, and hydrogenated xylene diisocyanate; and aromatic polyisocyanates such as 2,4-tolylene diisocyanate, 2,6-tolylene diisocyanate, 4,4′-diphenylmethane diisocyanate, and xylylene diisocyanate. A trimethylolpropane/tolylene diisocyanate trimeric adduct (Coronate L manufactured by Nippon Polyurethane Industry Co., Ltd.), and a trimethylolpropane/hexamethylene diisocyanate trimeric adduct (Coronate HL manufactured by Nippon Polyurethane Industry Co., Ltd.) can also be used. Examples of the epoxy crosslinking agent include N,N,N′,N′-tetraglycidyl-m-xylenediamine, diglycidylaniline, 1,3-bis(N,N-glycidylaminomethyl)cyclohexane, 1,6-hexanediol diglycidylether, neopentylglycol diglycidylether, ethyleneglycol diglycidylether, propyleneglycol diglycidylether, polyethyleneglycol diglycidylether, polypropyleneglycol diglycidylether, sorbitol polyglycidylether, glycerol polyglycidylether, pentaerithritol polyglycidylether, polyglycerol polyglycidylether, sorbitan polyglycidylether, trimethylolpropane polyglycidylether, diglycidyl adipate, o-diglycidyl phthalate, triglycidyl-tris(2-hydroxyethyl)isocyanurate, resorcin diglycidylether, bisphenol-5-diglycidylether; and an epoxy resin having two or more epoxy groups in a molecule.

In the first aspect of the present invention, a crosslinking treatment can be performed by irradiation with an electron beam, an ultraviolet ray, or the like instead of using the crosslinking agent or in addition to the use of the crosslinking agent.

The pressure-sensitive adhesive layer 32 can be formed by a common method of forming a sheet-like layer by mixing the pressure-sensitive adhesive with a solvent, other additives, and the like as necessary. Specifically, the pressure-sensitive adhesive layer 32 can be produced by a method of applying the pressure-sensitive adhesive or a mixture containing the pressure-sensitive adhesive, a solvent and other additives to the substrate 31, a method of forming the pressure-sensitive adhesive layer 32 by applying the above-described mixture to an appropriate separator (release paper, for example), and transferring (adhering) the resultant onto the substrate 31, for example.

The thickness of the pressure-sensitive adhesive layer 32 is not especially limited, and is about 5 to 300 μm (preferably 5 to 200 μm, more preferably 5 to 100 μm, and especially preferably 7 to 50 μm). When the thickness of the pressure-sensitive adhesive layer 32 is in the above-described range, adequate adhesive power can be exhibited. The pressure-sensitive adhesive layer 32 may be a single layer or a plurality of layers.

The adhering strength (23° C., peeling angle 180°, peeling speed 300 mm/min) of the pressure-sensitive adhesive layer 32 of the dicing tape 3 to the film 2 for a rear surface of a semiconductor is preferably in a range of 0.02 N/20 mm to 10 N/20 mm, and more preferably 0.05 N/20 mm to 5N/20 mm. By making the adhering strength 0.02 N/20 mm or more, chip flying of a semiconductor element can be prevented when dicing the semiconductor wafer. Meanwhile, by making the adhering strength 10 N/20 mm or less, difficulty in peeling the semiconductor element off and generation of adhesive residue can be prevented when picking the semiconductor element up.

The film 2 for a rear surface of a semiconductor and the dicing tape integrated film 1 for the backside of a semiconductor may be formed in a form in which the films are wound into a roll or a form in which the films are laminated. When the film have a form in which they are wound into a roll, the film 2 for a rear surface of a flip-chip type semiconductor or a dicing tape integrated film 1 for the backside of a semiconductor having a form in which the films are wound into a roll can be produced by winding the film 2 for a rear surface of a flip-chip type semiconductor or a laminated body of the film 2 for a rear surface of a flip-chip type semiconductor and the dicing tape 3 into a roll while protecting the film or the laminated body with a separator as necessary. The dicing tape integrated film 1 for the backside of a semiconductor that is wound into a roll may be configured with the substrate 31, the pressure-sensitive adhesive layer 32 that is formed on one side of the substrate 31, a film for a rear surface of a semiconductor that is formed on the pressure-sensitive adhesive layer 32, and a release treatment layer (a back treatment layer) that is formed on the other surface of the substrate 31.

The thickness (total thickness of the thickness of the film for a rear surface of a semiconductor and the thickness of the dicing tape made of the substrate 31 and the pressure-sensitive adhesive layer 32) of the dicing tape integrated film 1 for the backside of a semiconductor can be selected from a range of 8 to 1500 μm, preferably 20 to 850 μm, more preferably 31 to 500 μm, and especially preferably 47 to 330 μm.

By controlling the ratio between the thickness of the film 2 for a rear surface of a flip-chip type semiconductor and the thickness of the pressure-sensitive adhesive layer 32 of the dicing tape 3 and the ratio between the thickness of the film 2 for a rear surface of a flip-chip type semiconductor and the thickness of the dicing tape 3 (total thickness of the substrate 31 and the pressure-sensitive adhesive layer 32) in the dicing tape integrated film 1 for the backside of a semiconductor, the dicing property in a dicing step, the pickup property in a pickup step, and the like can be improved, and the dicing tape integrated film 1 for the backside of a semiconductor can be effectively used from the dicing step of a semiconductor wafer to the flip-chip bonding step of a semiconductor chip (for example, a semiconductor element).

### (Method of Manufacturing Dicing Tape Integrated Film for a Rear Surface of Semiconductor)

A method of manufacturing the dicing tape integrated film for a rear surface of a semiconductor according to this embodiment is explained using the dicing tape integrated film 1 for the backside of a semiconductor shown in FIG. 1 as an example. First, the substrate 31 can be formed by a conventionally known film forming method. When an antistatic agent is contained in the substrate 31, the antistatic agent is appropriately added in the material for forming a substrate in advance. Examples of the film forming method include a calender film forming method, a casting method in an organic solvent, an inflation extrusion method in a closed system, a T die extrusion method, a co-extrusion method, and a dry laminating method.

The pressure-sensitive adhesive layer 32 is formed by applying a pressure-sensitive adhesive composition to the substrate 31 and drying the composition (by crosslinking by heat as necessary). When an antistatic agent is contained in the pressure-sensitive adhesive layer 32, the antistatic agent is appropriately added in the pressure-sensitive adhesive composition in advance. Examples of the application method include roll coating, screen coating, and gravure coating. The pressure-sensitive adhesive layer 32 may be formed on the substrate 31 by applying the pressure-sensitive adhesive composition directly to the substrate 31, or the pressure-sensitive adhesive layer 32 may be transferred to the substrate 31 after the pressure-sensitive adhesive layer 32 is formed by applying the pressure-sensitive adhesive composition to a release paper whose surface has been subjected to a release treatment. With this configuration, the dicing tape 3 is produced in which the pressure-sensitive adhesive layer 32 is formed on the substrate 31.

The material for forming the film 2 for a rear surface of a semiconductor is applied onto release paper to have a prescribed thickness after drying, and further dried under a prescribed condition (a heat treatment is performed as necessary to dry the material when thermal curing is necessary) to form a coating layer. When an antistatic agent is contained in the film 2 for a rear surface of a semiconductor, the antistatic agent is appropriately added in the material for forming the film 2 for a rear surface of a semiconductor in advance. The coating layer is transcribed onto the pressure-sensitive adhesive layer 3 to form the film 2 for a rear surface of a semiconductor on the pressure-sensitive adhesive layer 32. The material for forming the film 2 for a rear surface of a semiconductor can be directly applied onto the pressure-sensitive adhesive layer 32 and dried under a prescribed condition (a heat treatment is performed as necessary to dry the material when thermal curing is necessary) to form the film 2 for a rear surface of a semiconductor on the pressure-sensitive adhesive layer 32. When the film 2 for a rear surface of a semiconductor has a multilayered structure, and an antistatic agent is contained in any one of outermost layers, the pressure-sensitive adhesive layer 32 is preferably formed on the outermost layer containing the antistatic agent. With the above, the dicing tape integrated film 1 for the backside of a semiconductor according to the first aspect of the present invention can be obtained. When thermal curing is performed to form the film 2 for a rear surface of a semiconductor, it is important to perform thermal curing up to a level at which the film is partially cured. However, it is preferable not to perform thermal curing.

The dicing tape integrated film 1 for the backside of a semiconductor of the first aspect of the present invention can be used suitably in the manufacture of a semiconductor device having a flip-chip connecting step. The dicing tape integrated film 1 for the backside of a semiconductor of the first aspect of the present invention is used to manufacture a flip-chip mounted semiconductor device, and the flip-chip mounted semiconductor device is manufactured in a form in which the film 2 for a rear surface of a semiconductor of the dicing tape integrated film 1 for the backside of a semiconductor is pasted to the backside of the semiconductor element. Therefore, the dicing tape integrated film 1 for the backside of a semiconductor of the first aspect of the present invention can be used for a flip-chip mounted semiconductor device (a semiconductor device in a form in which the semiconductor element is fixed to an adherend such as a substrate by a flip-chip bonding method).

### (Semiconductor Wafer)

The semiconductor wafer is not especially limited as long as it is a known or common semiconductor wafer, and semiconductor wafers made of various materials can be appropriately selected and used. In the present invention, a silicon wafer can be suitably used as the semiconductor wafer.

### (Method of Manufacturing Semiconductor Device)

The method of manufacturing a semiconductor device of the first aspect of the present invention is a method of manufacturing a semiconductor device including at least the steps of bonding a semiconductor wafer onto the adhesive sheet of the dicing tape integrated adhesive sheet, dicing the semiconductor wafer to form a semiconductor element, and picking up the semiconductor element from the pressure-sensitive adhesive layer of the dicing tape together with the adhesive sheet.

Particularly, when the adhesive sheet of the first aspect of the present invention is the film for a rear surface of a semiconductor, the method of manufacturing a semiconductor device includes at least the steps of bonding a semiconductor wafer onto the dicing tape integrated film for a rear surface of a semiconductor, dicing the semiconductor wafer, picking up the semiconductor element obtained by dicing, and flip-chip bonding the semiconductor element onto an adherend.

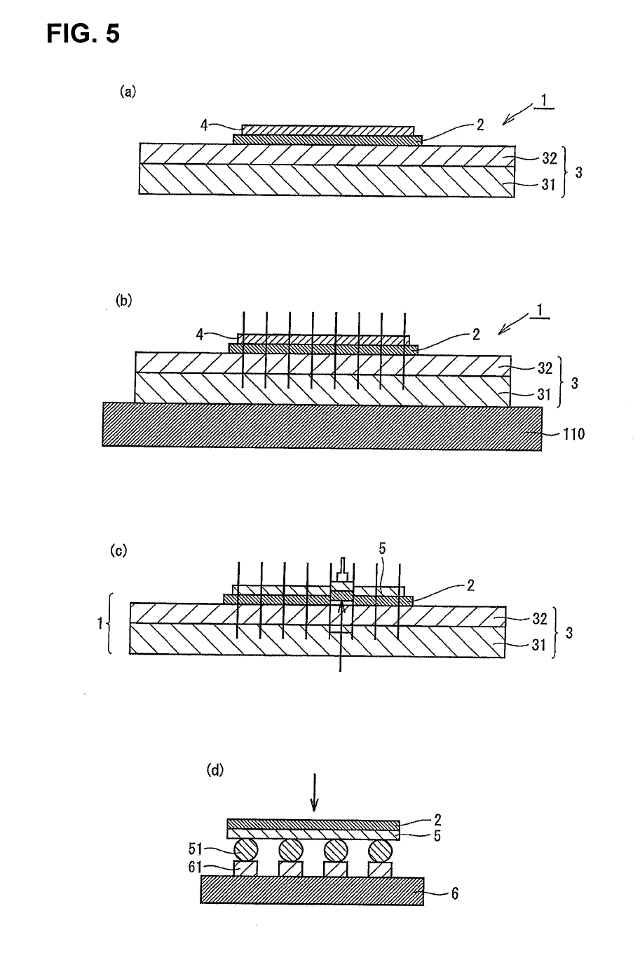

The method of manufacturing a semiconductor device according to the present embodiment will be described below with reference to FIG. 5. FIGS. 5 (A) to 5 (D) are schematic sectional views showing one example of the method of manufacturing a semiconductor using the dicing tape integrated film 1 for a rear surface of a semiconductor according to the present embodiment.

### [Mounting Step]

As shown in FIG. 2 (a), the separator that is appropriately provided on the film 2 for a rear surface of a semiconductor of the dicing tape integrated film 1 for the backside of a semiconductor is appropriately peeled off, a semiconductor wafer 4 is pasted to the film 2 for a rear surface of a semiconductor, and the laminate is fixed by adhering and holding (a mounting step). At this time, the film 2 for a rear surface of a semiconductor is uncured (including a condition of being partially cured). The dicing tape integrated film 1 for the backside of a semiconductor is pasted to the backside of the semiconductor wafer 4. The backside of the semiconductor wafer 4 means the surface opposite to the circuit surface (also referred to as a non-circuit surface or a non-electrode forming surface). The pasting method is not especially limited, and a pasting method by pressure-bonding is preferable. The pressure-bonding is performed by pressing by a pressing means such as a press roll.

[Dicing Step]

As shown in FIG. 5(B), the semiconductor wafer 4 is diced. Accordingly, the semiconductor wafer 4 is cut into individual pieces (small pieces) having a prescribed size, and a semiconductor chip 5 as a semiconductor element is manufactured. The dicing is performed in a state where the dicing tape 3 is vacuum-chucked on a suction table 110 from the circuit surface side of the semiconductor wafer 4 in accordance with a normal method. For example, a cutting method called full cut in which cutting is performed up to the dicing tape integrated film 1 for the backside of a semiconductor can be adopted in this step. The dicing apparatus used in this step is not especially limited, and a conventionally known apparatus can be used. Because the semiconductor wafer 4 is adhered and fixed with excellent adhesion by the dicing tape integrated film 1 for the backside of a semiconductor having the film for a rear surface of a semiconductor, chip cracks and chip fly can be suppressed and damages to the semiconductor wafer 4 can also be suppressed. When the film 2 for a rear surface of a semiconductor is formed of a resin composition containing an epoxy resin, the occurrence of protrusion of the adhesive layer of the film for a rear surface of a semiconductor at a surface cut by dicing can be suppressed or prevented. As a result, reattachment (blocking) of the cut surfaces can be suppressed or prevented, and pickup described later can be performed more favorably.

When expanding the dicing tape integrated film 1 for the backside of a semiconductor, a conventionally known expanding apparatus can be used. The expanding apparatus has a donut-shaped outer ring that can push down the dicing tape integrated film 1 for the backside of a semiconductor through a dicing ring and an inner ring that has a smaller diameter than the outer ring and that supports the dicing tape integrated film for a rear surface of a semiconductor. With this expanding step, generation of damages caused by the contact between adjacent semiconductor chips can be prevented in the pickup step described later.

### [Pickup Step]

The semiconductor chip 5 is peeled from the dicing tape 3 together with the film 2 for a rear surface of a semiconductor by performing pickup of the semiconductor chip 5 as shown in FIG. 5(c) to collect the semiconductor chip 5 that is adhered and fixed to the dicing tape integrated film 1 for the backside of a semiconductor. The pickup method is not especially limited, and various conventionally known methods can be adopted. An example of the method is a method of pushing up an individual semiconductor chip 5 from the side of the substrate 31 of the dicing tape integrated film 1 for the backside of a semiconductor with a needle and picking up the pushed semiconductor chip 5 with a pickup apparatus. The backside of the semiconductor chip 5 that is picked up is protected by the film 2 for a rear surface of a semiconductor.

### [Flip-Chip Connecting Step]

As shown in FIG. 5(d), the semiconductor chip 5 that is picked up is fixed to an adherend such as a substrate by a flip-chip bonding method (flip-chip mounting method). Specifically, the semiconductor chip 5 is fixed to an adherend 6 by a normal method in a form that the circuit surface (also referred to as the surface, a circuit pattern forming surface, or an electrode forming surface) of the semiconductor chip 5 faces the adherend 6. The semiconductor chip 5 can be fixed to the adherend 6 while securing electrical conduction of the semiconductor chip 5 with the adherend 6 by contacting and pressing a bump 51 formed on the circuit surface side of the semiconductor chip 5 to a conductive material 61 such as solder for bonding that is adhered to a connection pad of the adherend 6 and melting the conductive material (a flip-chip bonding step). At this time, a space is formed between the semiconductor chip 5 and the adherend 6, and the distance of the space is generally about 30 to 300 μm. After flip-chip bonding (flip-chip connection) of the semiconductor chip 5 onto the adherend 6, it is important to wash the facing surface and the space between the semiconductor chip 5 to the adherend 6 and to seal the space by filling the space with a sealing material such as a sealing resin.

Various substrates such as a lead frame and a circuit board (a wiring circuit board, for example) can be used as the adherend 6. The material of the substrate is not especially limited, and examples thereof include a ceramic substrate and a plastic substrate. Examples of the plastic substrate include an epoxy substrate, a bismaleimide triazine substrate, and a polyimide substrate.

The material of the bump and the conductive material in the flip-chip bonding step are not especially limited, and examples thereof include solders (alloys) of a tin-lead metal material, a tin-silver metal material, a tin-silver-copper metal material, a tin-zinc metal material, and a tin-zinc-bismuth metal material, a gold metal material, and a copper metal material.

In the flip-chip bonding step, the bump of the circuit surface side of the semiconductor chip 5 and the conductive material on the surface of the adherend 6 are connected by melting the conductive material. The temperature when the conductive material is molten is normally about 260° C. (250 to 300° C., for example). The dicing tape integrated film for a rear surface of a semiconductor of the first aspect of the present invention can have heat resistance so that it can resist a high temperature in the flip-chip bonding step by forming the film for a rear surface of a semiconductor with an epoxy resin, or the like.

In this step, the facing surface (an electrode forming surface) and the space between the semiconductor chip 5 and the adherend 6 are preferably washed. The washing liquid that is used in washing is not especially limited, and examples thereof include an organic washing liquid and a water washing liquid. The film for a rear surface of a semiconductor in the dicing tape integrated film for a rear surface of a semiconductor of the first aspect of the present invention has solvent resistance to the washing liquid, and does not substantially have solubility in these washing liquids. Because of that, various washing liquids can be used as the washing liquid, and washing can be performed by a conventional method without requiring a special washing liquid.

Next, a sealing step is performed to seal the space between the flip-chip bonded semiconductor chip 5 and the adherend 6. The sealing step is performed using a sealing resin. The sealing condition is not especially limited. Thermal curing of the sealing resin is performed normally by heating the sealing resin at 175° C. for 60 to 90 seconds. However, the present invention is not limited to this, and curing can be performed at 165 to 185° C. for a few minutes, for example. At this time, the tensile storage elastic modulus of the film 2 for a rear surface of a semiconductor is relatively high because the film 2 contains an inorganic filler in an amount of 70% by weight or more to the entire film 2 for a rear surface of a semiconductor. As a result, warping of the semiconductor chip that can be generated during the thermal curing of the sealing resin can be effectively suppressed or prevented. With this step, the film 2 for a rear surface of a semiconductor can be completely or almost completely thermally cured, and the layer can be pasted to the backside of the semiconductor element with excellent adhesion. Because the film 2 for a rear surface of a semiconductor according to the first aspect of the present invention can be thermally cured together with the sealing material in the sealing step even when the layer is uncured before this step, there is no necessity to add a new step to thermally cure the film 2 for a rear surface of a semiconductor.

The sealing resin is not especially limited as long as it is a resin having insulation properties, and can be appropriately selected from sealing materials such as a known sealing resin. However, an insulating resin having elasticity is preferable. Examples of the sealing resin include a resin composition containing an epoxy resin. Examples of the epoxy resin include epoxy resins described above. The sealing resin with a resin composition containing an epoxy resin may contain a thermosetting resin such as a phenol resin other than the epoxy resin, a thermoplastic resin, and the like as a resin component besides the epoxy resin. The phenol resin can also be used as a curing agent for the epoxy resin, and examples of the phenol resin include the above-described phenol resins.

Because the film for a rear surface of a semiconductor is pasted to the backside of a semiconductor chip in the semiconductor device (flip-chip mounted semiconductor device) that is manufactured using the dicing tape integrated film 1 for the backside of a semiconductor, various markings can be performed with excellent visibility. Even when marking is performed by a laser marking method, marking can be performed with an excellent contrast ratio, and various information such as character information and graphic information marked by laser marking can be visually recognized well. A known laser marking apparatus can be used when performing laser marking. Various lasers such as a gas laser, a solid laser, and a liquid laser can be used. Specifically, the gas laser is not especially limited, and a known gas laser can be used. However, a carbon dioxide gas laser (CO₂ laser) and an excimer laser such as an ArF laser, a KrF laser, an XeCl laser, or an XeF laser are suitable. The solid laser is not especially limited, and a known solid laser can be used. However, a YAG laser such as an Nd:YAG laser and a YVO₄ laser are suitable.

Because the semiconductor device that is manufactured using the dicing tape integrated film for a rear surface of a semiconductor and the film for a rear surface of a semiconductor of the first aspect of the present invention is a semiconductor device that is mounted by a flip-chip mounting method, the semiconductor device has a shape thinner and smaller than a semiconductor device that is mounted by a die bonding mounting method. Because of this, the semiconductor device can be suitably used as various electronic apparatuses and electronic parts or materials and members thereof. Specific examples of the electronic apparatus in which the flip-chip mounted semiconductor device of the first aspect of the present invention can be used include a portable phone, PHS, a small computer such as PDA (personal digital assistant), a notebook personal computer, Netbook (trademark), or a wearable computer, a small electronic apparatus in which a portable phone and a computer are integrated, Digital Camera (trademark), a digital video camera, a small television, a small game machine, a small digital audio player, an electronic organizer, an electronic dictionary, an electronic apparatus terminal for an electronic book, and a mobile electronic apparatus (portable electronic apparatus) such as a small digital type clock or watch. Examples of the electronic apparatus also include an electronic apparatus other than a mobile type apparatus (i.e., a stationary apparatus) such as a desktop personal computer, a flat-panel television, an electronic apparatus for recording and playing such as a hard disc recorder or a DVD player, a projector, or a micromachine. Examples of the electronic parts or materials and members of the electronic apparatus and electronic parts include a component of CPU and components of various recording apparatuses such as a memory and a hard disk.

In the above-described embodiment, the case is described in which the adhesive sheet of the first aspect of the present invention is the film 2 for a rear surface of a flip-chip semiconductor. However, the adhesive sheet of the first aspect of the present invention is not limited thereto. The adhesive sheet of the first aspect of the present invention is not particularly limited as long as it is formed on a dicing tape and used, and examples thereof may include a die bond film and an underfill sheet.

When the adhesive sheet of the first aspect of the present invention is a die bond film, the same configuration as that of the film for a rear surface of a flip-chip semiconductor can be adopted after the compositions and the contents are changed to the extent that the sheet functions as a die bond film. The method of manufacturing a semiconductor device is the same as the method of manufacturing a semiconductor device in which the dicing tape integrated film 1 for a rear surface of a semiconductor is used except for performing the step of die bonding a semiconductor element (for example, a semiconductor chip) to an adherend with a die bond film interposed therebetween in place of the flip-chip bonding step. That is, the method of manufacturing a semiconductor device using the dicing tape integrated die bond film includes the steps of bonding a semiconductor wafer onto a die bond film of the dicing tape integrated die bond film, dicing the semiconductor wafer to form a semiconductor element, picking up the semiconductor element from the pressure-sensitive adhesive layer of the dicing tape together with the die bond film, and die bonding the semiconductor element to an adherend with the die bond film interposed therebetween.

When the adhesive sheet of the first aspect of the present invention is an underfill sheet, the same configuration as that of the film for a rear surface of a flip-chip semiconductor can be adopted after the compositions and the contents are changed to the extent that the sheet functions as an underfill sheet. The method of manufacturing a semiconductor device is the same as the method of manufacturing a semiconductor device in which the dicing tape integrated film 1 for a rear surface of a semiconductor is used except for bonding a dicing tape integrated underfill sheet as the dicing tape integrated adhesive sheet to the circuit surface side of the semiconductor wafer in the mounting step in place of bonding the dicing tape integrated film 1 for a rear surface of a semiconductor as the dicing tape integrated adhesive sheet to a rear surface of the semiconductor wafer. That is, the method of manufacturing a semiconductor device using the dicing tape integrated underfill sheet includes the steps of bonding the circuit surface side of a semiconductor wafer onto an underfill sheet of the dicing tape integrated underfill sheet, dicing the semiconductor wafer to form a semiconductor element, picking up the semiconductor element from the pressure-sensitive adhesive layer of the dicing tape together with the underfill sheet, and flip-chip bonding the semiconductor element onto an adherend with the underfill sheet interposed therebetween.

### <Second Aspect of Present Invention>

The points of the embodiment of the second aspect of the present invention will be described below which differ from the first aspect of the present invention. The dicing tape integrated adhesive sheet of the second aspect of the present invention can have the same configuration as that of the first aspect of the present invention except for the items particularly described in the section of the second aspect of the present invention. Therefore, the descriptions of portions that are common with the first aspect of the present invention are omitted.

### (Dicing Tape Integrated Film for Rear Surface of Semiconductor)

The embodiment of the dicing tape integrated film for a rear surface of a semiconductor according to the second aspect of the present invention (referred to as the second embodiment below) has the same configuration as that of the embodiment of the dicing tape integrated film for a rear surface of a semiconductor according to the first aspect of the present invention. That is, the second embodiment may include the dicing tape integrated film 1 for a rear surface of a semiconductor as shown in FIG. 1. The layer configuration of the dicing tape integrated film 1 for a rear surface of a semiconductor has been described in the section of the first aspect of the present invention. Therefore, its description is omitted herein.

In the dicing tape integrated film 1 for a rear surface of a semiconductor according to the second embodiment, at least one surface of the substrate 31 and the pressure-sensitive adhesive layer 32 has a surface resistivity of 1.0×10¹¹Ω or less, preferably 1.0×10¹⁹Ω or less, and more preferably 1.0×10⁹Ω or less.

Particularly, when an antistatic agent is contained in the substrate 31, the surface of the substrate 31 has a surface resistivity of preferably 1.0×10¹¹Ω or less, more preferably 1.0×10¹⁹Ω or less, and further preferably 1.0×10⁹Ω or less.

Particularly, when the substrate 31 has a multilayered structure, and an antistatic agent is contained in at least one of outermost layers of the multilayered substrate 31, the surface of the outermost layer containing an antistatic agent has a surface resistivity of preferably 1.0×10¹¹Ω or less, more preferably 1.0×10¹⁹Ω or less, and further preferably 1.0×10⁹Ω or less.

When an antistatic agent is contained in the pressure-sensitive adhesive layer 32, the surface of the pressure-sensitive adhesive layer 32 has a surface resistivity of preferably 1.0×10¹¹Ω or less, more preferably 1.0×10¹⁰ Ω or less, and further preferably 1.0×10⁹Ω or less.

When an antistatic agent is contained in both the substrate 31 and the pressure-sensitive adhesive layer 32, the surface of the substrate 31 has a surface resistivity of preferably 1.0×10¹¹Ω or less, more preferably 1.0×10¹⁹Ω or less, and further preferably 1.0×10⁹Ω or less, and the surface of the pressure-sensitive adhesive layer 32 has a surface resistivity of preferably 1.0×10¹¹Ω or less, more preferably 1.0×10¹⁰Ω or less, and further preferably 1.0×10⁹Ω or less.

The smaller the surface resistivity is, the more preferable it is, and examples of the surface resistivity may include 1.0×10⁵Ω or more, 1.0×10⁶Ω or more, and 1.0×10⁷Ω or more. Because the surface resistivity is 1.0×10¹¹Ω or less, the electrification less likely occurs. Therefore, an antistatic effect can be further exhibited. In the present invention, the surface resistivity of at least one surface of the substrate and the pressure-sensitive adhesive layer refers to the surface resistivity of at least one of the surface of the substrate of the pressure-sensitive adhesive layer side, the surface of the substrate opposite the pressure-sensitive adhesive layer, the surface of the pressure-sensitive adhesive layer of the substrate side, and the surface of the pressure-sensitive adhesive layer opposite the substrate. The surface resistivity is a value that is measured with a method described in Examples.

In the dicing tape integrated film 1 for a rear surface of a semiconductor according to the second embodiment, a peeling force between the pressure-sensitive adhesive layer 32 and the adhesive sheet 2 is preferably 0.02 to 0.5 N/20 mm, more preferably 0.02 to 0.3 N/20 mm, and further preferably 0.02 to 0.2 N/20 mm obtained with a peeling test at a peeling rate of 10 m/minute and a peeling angle of 150°. When the peeling force is 0.02 N/20 mm or more, the semiconductor wafer can be fixed during dicing. When the peeling force is 0.5 N/20 mm or less, the semiconductor element with the adhesive sheet 2 can be easily peeled off from the pressure-sensitive adhesive layer 32.

In the dicing tape integrated film 1 for a rear surface of a semiconductor according to the second embodiment, an absolute value of a peeling electrification voltage generated when the pressure-sensitive adhesive layer 32 and the adhesive sheet 2 are peeled off under conditions of the peeling test is preferably 0.5 kV or less (−0.5 kV to +0.5 kV), more preferably 0.3 kV or less (−0.3 kV to +0.3 kV), and further preferably 0.2 kV or less (−0.2 kV to +0.2 kV). When the absolute value of a peeling electrification voltage is 0.5 kV or less at the time when the pressure-sensitive adhesive layer 32 and the adhesive sheet 2 are peeled off under conditions of the peeling test, an antistatic effect can be further exhibited. As a result, breakdown of the semiconductor element caused by the peeling electrification during pickup is prevented, and the reliability as a device can be improved.

### <Third Aspect of Present Invention>

The points of the embodiment of the third aspect of the present invention will be described below which differ from the first aspect of the present invention. The dicing tape integrated adhesive sheet of the third aspect of the present invention can have the same configuration as that of the first aspect of the present invention except for the items particularly described in the section of the third aspect of the present invention. Therefore, the descriptions of portions that are common with the first aspect of the present invention are omitted.

### (Dicing Tape Integrated Film for Rear Surface of Semiconductor)

The embodiment of the dicing tape integrated film for a rear surface of a semiconductor according to the third aspect of the present invention (referred to as the third embodiment below) has the same configuration as that of the embodiment of the dicing tape integrated film for a rear surface of a semiconductor according to the first aspect of the present invention. That is, the third embodiment may include the dicing tape integrated film 1 for a rear surface of a semiconductor as shown in FIG. 1. The layer configuration of the dicing tape integrated film 1 for a rear surface of a semiconductor has been described in the section of the first aspect of the present invention. Therefore, its description is omitted herein.

In the dicing tape integrated film 1 for a rear surface of a semiconductor according to the third embodiment, a polymeric antistatic agent is contained in at least one of the substrate 31 and the pressure-sensitive adhesive layer 32. Because a polymeric antistatic agent is contained in at least one of the substrate 31 and the pressure-sensitive adhesive layer 32 of the dicing tape integrated film 1 for a rear surface of a semiconductor, the electrification less likely occurs. Therefore, an antistatic effect can be exhibited. Because a polymeric antistatic agent is used as the antistatic agent, bleeding of the agent from the substrate 31 or the pressure-sensitive adhesive layer 32 less likely occurs. As a result, a decrease in antistatic function over time can be suppressed. Particularly, when a polymeric antistatic agent is contained in the substrate 31, the peeling electrification between the substrate 31 and a suction table when the dicing tape 3 is removed from the suction table that fixes the dicing tape 3 can be suppressed. Above all, when the substrate 31 has a multilayered structure and a polymeric antistatic agent is contained in the outermost layer of the pressure-sensitive adhesive layer 32 side of the multilayered substrate 31, the electrification of both the substrate 31 and the pressure-sensitive adhesive layer 32 can be suppressed. When a polymeric antistatic agent is contained in the outermost layer opposite the pressure-sensitive adhesive layer 32 side of the multilayered substrate 31, the peeling electrification between the substrate 31 and the suction table can be more effectively suppressed.

A polymeric antistatic agent may be contained in the film 2 for a rear surface of a semiconductor. When a polymeric antistatic agent is contained in the film 2 for a rear surface of a semiconductor, the film 2 has an antistatic effect even after it is peeled off from the dicing tape 3. As a result, breakdown of the semiconductor element caused by electrification can be suppressed even after the film 2 is peeled off from the dicing tape 3. Particularly, when the film 2 for a rear surface of a semiconductor has a multilayered structure and a polymeric antistatic agent is contained in the outermost layer of the dicing tape 3 side of the multilayered film 2 for a rear surface of a semiconductor, the peeling electrification generated when the pressure-sensitive adhesive layer 32 and the film 2 for a rear surface of a semiconductor are peeled off can be more effectively suppressed. The polymeric antistatic agent is as described in the section of the first aspect of the present invention.

In the dicing tape integrated film 1 for a rear surface of a semiconductor according to the third embodiment, at least one surface of the substrate 31 and the pressure-sensitive adhesive layer 32 has a surface resistivity of preferably 1.0×10¹¹Ω or less, more preferably 1.0×10¹⁰Ω or less, and further preferably 1.0×10⁹Ω or less. Particularly, when a polymeric antistatic agent is contained in the substrate 31, the surface of the substrate 31 has a surface resistivity of preferably 1.0×10¹¹Ω or less, more preferably 1.0×10¹⁰Ω or less, and further preferably 1.0×10⁹Ω or less. Particularly, when the substrate 31 has a multilayered structure, and a polymeric antistatic agent is contained in at least one of the outermost layers of the multilayered substrate 31, the surface of the outermost layer containing a polymeric antistatic agent has a surface resistivity of preferably 1.0×10¹¹Ω or less, more preferably 1.0×10¹⁰Ω or less, and further preferably 1.0×10⁹Ω or less.

When a polymeric antistatic agent is contained in the pressure-sensitive adhesive layer 32, the surface of the pressure-sensitive adhesive layer 32 has a surface resistivity of preferably 1.0×10¹¹Ω or less, more preferably 1.0×10¹⁰Ω or less, and further preferably 1.0×10⁹Ω or less.

When a polymeric antistatic agent is contained in both the substrate 31 and the pressure-sensitive adhesive layer 32, the surface of the substrate 31 has a surface resistivity of preferably 1.0×10¹¹Ω or less, more preferably 1.0×10¹⁰Ω or less, and further preferably 1.0×10⁹Ω or less, and the surface of the pressure-sensitive adhesive layer 32 has a surface resistivity of preferably 1.0×10¹¹Ω or less, more preferably 1.0×10¹⁰Ω or less, and further preferably 1.0×10⁹Ω or less.

The smaller the surface resistivity is, the more preferable it is, and examples of the surface resistivity may include 1.0×10⁵Ω or more, 1.0×10⁶Ω or more, and 1.0×10⁷Ω or more. When the surface resistivity is 1.0×10¹¹Ω or less, the electrification less likely occurs. Therefore, an antistatic effect can be further exhibited. In the third aspect of the present invention, the surface resistivity of at least one surface of the substrate and the pressure-sensitive adhesive layer refers to the surface resistivity of at least one of the surface of the substrate of the pressure-sensitive adhesive layer side, the surface of the substrate opposite the pressure-sensitive adhesive layer, the surface of the pressure-sensitive adhesive layer of the substrate side, and the surface of the pressure-sensitive adhesive layer opposite the substrate. The surface resistivity is a value that is measured with a method described in Examples.

In the dicing tape integrated film 1 for a rear surface of a semiconductor according to the third embodiment, the peeling force between the pressure-sensitive adhesive layer 32 and the adhesive sheet 2 obtained with a peeling test at peeling rate of 10 m/minute and peeling angle of 150° is preferably 0.02 to 0.5 N/20 mm, more preferably 0.02 to 0.3 N/20 mm, and further preferably 0.02 to 0.2 N/20 mm. When the peeling force is 0.02 N/20 mm or more, the semiconductor wafer can be fixed during dicing. When the peeling force is 0.5 N/20 mm or less, the semiconductor element with the adhesive sheet 2 can be easily peeled off from the pressure-sensitive adhesive layer 32.

In the dicing tape integrated film 1 for a rear surface of a semiconductor according to the third embodiment, an absolute value of a peeling electrification voltage generated when the pressure-sensitive adhesive layer 32 and the adhesive sheet 2 are peeled off under conditions of the peeling test is preferably 0.5 kV or less (−0.5 kV to +0.5 kV), more preferably 0.3 kV or less (−0.3 kV to +0.3 kV), and further preferably 0.2 kV or less (−0.2 kV to +0.2 kV). When the absolute value of a peeling electrification voltage is 0.5 kV or less at the time when the pressure-sensitive adhesive layer 32 and the adhesive sheet 2 are peeled off under conditions of the peeling test, an antistatic effect can be further exhibited. As a result, breakdown of the semiconductor element caused by the peeling electrification during pickup is prevented, and the reliability as a device can be improved.

### <Fourth Aspect of Present Invention>

The points of the embodiment of the fourth aspect of the present invention will be described below which differ from the first aspect of the present invention. The dicing tape integrated adhesive sheet of the fourth aspect of the present invention can have the same configuration as that of the first aspect of the present invention except for the items particularly described in the section of the fourth aspect of the present invention. Therefore, the descriptions of portions that are common with the first aspect of the present invention are omitted.

### (Dicing Tape Integrated Film for Rear Surface of Semiconductor)

The embodiment of the dicing tape integrated film for a rear surface of a semiconductor according to the fourth aspect of the present invention (referred to as the fourth embodiment below) has the same configuration as that of the embodiment of the dicing tape integrated film for a rear surface of a semiconductor according to the first aspect of the present invention. That is, the fourth embodiment may include the dicing tape integrated film 1 for a rear surface of a semiconductor as shown in FIG. 1. The layer configuration of the dicing tape integrated film 1 for a rear surface of a semiconductor has been described in the section of the first aspect of the present invention. Therefore, its description is omitted herein.

Any surface of the film 2 for a rear surface of a semiconductor according to the fourth embodiment has a surface resistivity of 1.0×10¹¹Ω or less, preferably 1.0×10¹⁰Ω or less, and more preferably 1.0×10⁹Ω or less. When the film 2 for a rear surface of a semiconductor has a multilayered structure, and an antistatic agent is contained in any one of the outermost layers, the outermost layer containing an antistatic agent has a surface resistivity of preferably 1.0×10¹¹Ω or less, more preferably 1.0×10¹⁹Ω or less, and further preferably 1.0×10⁹Ω or less. The smaller the surface resistivity is, the more preferable it is, and examples of the surface resistivity may include 1.0×10⁵Ω or more, 1.0×10⁶Ω or more, and 1.0×10⁷Ω or more. Because the surface resistivity is 1.0×10¹¹Ω or less, the electrification less likely occurs. Therefore, an antistatic effect can be further exhibited. The surface resistivity is a value that is measured with a method described in Examples.

In the dicing tape integrated film 1 for a rear surface of a semiconductor according to the fourth embodiment, a peeling force between the pressure-sensitive adhesive layer 32 and the adhesive sheet 2 is preferably 0.02 to 0.5N/20 mm, more preferably 0.02 to 0.3 N/20 mm, and further preferably 0.02 to 0.2 N/20 mm obtained with a peeling test at a peeling rate of 10 m/minute and a peeling angle of 150°. When the peeling force is 0.02 N/20 mm or more, the semiconductor wafer can be fixed during dicing. When the peeling force is 0.5 N/20 mm or less, the semiconductor element with the adhesive sheet 2 can be easily peeled off from the pressure-sensitive adhesive layer 32.

In the dicing tape integrated film 1 for a rear surface of a semiconductor according to the fourth embodiment, an absolute value of a peeling electrification voltage generated when the pressure-sensitive adhesive layer 32 and the adhesive sheet 2 are peeled off under conditions of the peeling test is preferably 0.5 kV or less (−0.5 kV to +0.5 kV), more preferably 0.3 kV or less (−0.3 kV to +0.3 kV), and further preferably 0.2 kV or less (−0.2 kV to +0.2 kV). When the absolute value of a peeling electrification voltage is 0.5 kV or less at the time when the pressure-sensitive adhesive layer 32 and the adhesive sheet 2 are peeled off under conditions of the peeling test, an antistatic effect can be further exhibited. As a result, breakdown of the semiconductor element caused by the peeling electrification during pickup is prevented, and the reliability as a device can be improved.

When the film 2 for a rear surface of a semiconductor according to the fourth embodiment is not laminated on the dicing tape 3, the film 2 for a rear surface of a semiconductor may be protected by a separator having a release layer on each of both surfaces in a form in which the film. 2 is wound into a roll using the separator, or it may be protected by a separator having a release layer on at least one of the surfaces.

The film 2 for a rear surface of a semiconductor according to the fourth embodiment can be bonded to a dicing tape to be used in a flip-chip mounted semiconductor device (a semiconductor device in a state or in the form where a semiconductor chip is fixed to an adherend such as a substrate with a flip-chip bonding manner) in the same manner as the dicing tape integrated film 1 for a rear surface of a semiconductor.

When a semiconductor device is manufactured by using a film for a rear surface of a flip-chip semiconductor such as the film 2 for a rear surface of a semiconductor, a semiconductor device can be manufactured by the method in accordance with the method of manufacturing a semiconductor device when the dicing tape integrated film 1 for a rear surface of a semiconductor is used. That is, the method of manufacturing a semiconductor device of the fourth aspect of the present invention is a method of manufacturing a semiconductor device including at least the steps of preparing a dicing tape in which a pressure-sensitive adhesive layer is laminated on a substrate, bonding the adhesive sheet onto the pressure-sensitive adhesive layer of the dicing tape to obtain a dicing tape integrated adhesive sheet, bonding a semiconductor wafer onto the adhesive sheet of the dicing tape integrated adhesive sheet, dicing the semiconductor wafer to form a semiconductor element, and picking up the semiconductor element from the pressure-sensitive adhesive layer of the dicing tape together with the adhesive sheet.

Particularly, when the adhesive sheet of the fourth aspect of the present invention is the film for a rear surface of a semiconductor, the method of manufacturing a semiconductor device includes at least the steps of preparing a dicing tape in which a pressure-sensitive adhesive layer is laminated on a substrate, bonding the film for a rear surface of a semiconductor onto the pressure-sensitive adhesive layer of the dicing tape to obtain a dicing tape integrated film for a rear surface of a semiconductor, bonding a rear surface of a semiconductor wafer onto the dicing tape integrated film for a rear surface of a semiconductor, dicing the semiconductor wafer, picking up a semiconductor element obtained by dicing, and flip-chip bonding the semiconductor element onto an adherend.

### <Fifth Aspect of Present Invention>

The points of the embodiment of the fifth aspect of the present invention will be described below which differ from the first aspect of the present invention. The dicing tape integrated adhesive sheet of the fifth aspect of the present invention can have the same configuration as that of the first aspect of the present invention except for the items particularly described in the section of the fifth aspect of the present invention. Therefore, the descriptions of portions that are common with the first aspect of the present invention are omitted.

### (Dicing Tape Integrated Film for Rear Surface of Semiconductor)

The embodiment of the dicing tape integrated film for a rear surface of a semiconductor according to the fifth aspect of the present invention (referred to as the fifth embodiment below) has the same configuration as that of the embodiment of the dicing tape integrated film for a rear surface of a semiconductor according to the first aspect of the present invention. That is, the fifth embodiment may include the dicing tape integrated film 1 for a rear surface of a semiconductor as shown in FIG. 1. The layer configuration of the dicing tape integrated film 1 for a rear surface of a semiconductor has been described in the section of the first aspect of the present invention. Therefore, its description is omitted herein.

A polymeric antistatic agent is contained in the film 2 for a rear surface of a semiconductor according to the fifth embodiment. Because a polymeric antistatic agent is contained in the film 2 for a rear surface of a semiconductor, the electrification less likely occurs. Because a polymeric antistatic agent is used as the antistatic agent, bleeding of the agent from the film 2 for a rear surface of a semiconductor less likely occurs. As a result, a decrease in antistatic function over time can be suppressed. Because a polymeric antistatic agent is contained in the film 2 for a rear surface of a semiconductor, the film 2 has an antistatic effect even after it is peeled off from the dicing tape when it is bonded to the dicing tape to be used as the dicing tape integrated adhesive sheet. As a result, breakdown of the semiconductor element caused by electrification can be suppressed even after the adhesive sheet is peeled off from the dicing tape. Particularly, when the film 2 for a rear surface of a semiconductor has a multilayered structure and a polymeric antistatic agent is contained in the outermost layer of the dicing tape 3 side of the multilayered film 2 for a rear surface of a semiconductor, the peeling electrification generated when the pressure-sensitive adhesive layer 32 and the film 2 for a rear surface of a semiconductor are peeled off can be more effectively suppressed.

A polymeric antistatic agent may be contained in at least one of the substrate 31 and the pressure-sensitive adhesive layer 32 of the dicing tape integrated film 1 for a rear surface of a semiconductor. When a polymeric antistatic agent is contained in at least one of the substrate 31 and the pressure-sensitive adhesive layer 32, the electrification further less likely occurs. Therefore, an antistatic effect can be further exhibited. Because a polymeric antistatic agent is used as the antistatic agent, bleeding of the agent from the substrate 31 or the pressure-sensitive adhesive layer 32 less likely occurs. As a result, a decrease in antistatic function over time can be suppressed. Particularly, when a polymeric antistatic agent is contained in the substrate 31, the peeling electrification between the substrate 31 and a suction table when the dicing tape 3 is removed from the suction table that fixes the dicing tape 3 can be suppressed. Above all, when the substrate 31 has a multilayered structure and a polymeric antistatic agent is contained in the outermost layer of the pressure-sensitive adhesive layer 32 side of the multilayered substrate 31, the electrification of both the substrate 31 and the pressure-sensitive adhesive layer 32 can be suppressed. When a polymeric antistatic agent is contained in the outermost layer opposite the pressure-sensitive adhesive layer 32 side of the multilayered substrate 31, the peeling electrification between the substrate 31 and the suction table can be more effectively suppressed. The polymeric antistatic agent is as described in the section of the first aspect of the present invention.

Any surface of the film 2 for a rear surface of a semiconductor according to the fifth embodiment has a surface resistivity of preferably 1.0×10¹¹Ω or less, more preferably 1.0×10¹⁰Ω or less, and further preferably 1.0×10⁹Ω or less. When the film 2 for a rear surface of a semiconductor has a multilayered structure, and a polymeric antistatic agent is contained in any one of the outermost layers, the outermost layer containing a polymeric antistatic agent has a surface resistivity of preferably 1.0×10¹¹Ω or less, more preferably 1.0×10¹⁰Ω or less, and further preferably 1.0×10⁹Ω or less. The smaller the surface resistivity is, the more preferable it is, and examples of the surface resistivity may include 1.0×10⁵Ω or more, 1.0×10⁶Ω or more, and 1.0×10⁷Ω or more. When the surface resistivity is 1.0×10¹¹Ω or less, the electrification less likely occurs. Therefore, an antistatic effect can be further exhibited. The surface resistivity is a value that is measured with a method described in Examples.

In the dicing tape integrated film 1 for a rear surface of a semiconductor according to the fifth embodiment, a peeling force between the pressure-sensitive adhesive layer 32 and the adhesive sheet 2 is preferably 0.02 to 0.5N/20 mm, more preferably 0.02 to 0.3 N/20 mm, and further preferably 0.02 to 0.2 N/20 mm obtained with a peeling test at a peeling rate of 10 m/minute and a peeling angle of 150°. When the peeling force is 0.02 N/20 mm or more, the semiconductor wafer can be fixed during dicing. When the peeling force is 0.5 N/20 mm or less, the semiconductor element with the adhesive sheet 2 can be easily peeled off from the pressure-sensitive adhesive layer 32.

In the dicing tape integrated film 1 for a rear surface of a semiconductor according to the fifth embodiment, an absolute value of a peeling electrification voltage generated when the pressure-sensitive adhesive layer 32 and the adhesive sheet 2 are peeled off under conditions of the peeling test is preferably 0.5 kV or less (−0.5 kV to +0.5 kV), more preferably 0.3 kV or less (−0.3 kV to +0.3 kV), and further preferably 0.2 kV or less (−0.2 kV to +0.2 kV). When the absolute value of a peeling electrification voltage is 0.5 kV or less at the time when the pressure-sensitive adhesive layer 32 and the adhesive sheet 2 are peeled off under conditions of the peeling test, an antistatic effect can be further exhibited. As a result, breakdown of the semiconductor element caused by the peeling electrification during pickup is prevented, and the reliability as a device can be improved.

When the film 2 for a rear surface of a semiconductor according to the fifth embodiment is not laminated on the dicing tape 3, the film 2 for a rear surface of a semiconductor may be protected by a separator having a release layer on each of both surfaces in a form in which the film 2 is wound into a roll using the separator, or it may be protected by a separator having a release layer on at least one of the surfaces.

The film 2 for a rear surface of a semiconductor according to the fifth embodiment can be bonded to a dicing tape to be used in a flip-chip mounted semiconductor device (a semiconductor device in a state or in the form where a semiconductor chip is fixed to an adherend such as a substrate with a flip-chip bonding manner) in the same manner as the dicing tape integrated film 1 for a rear surface of a semiconductor.

When a semiconductor device is manufactured by using a film for a rear surface of a flip-chip semiconductor such as the film 2 for a rear surface of a semiconductor, a semiconductor device can be manufactured by the method in accordance with the method of manufacturing a semiconductor device when the dicing tape integrated film 1 for a rear surface of a semiconductor is used. That is, the method of manufacturing a semiconductor device of the fifth aspect of the present invention is a method of manufacturing a semiconductor device including at least the steps of preparing a dicing tape in which a pressure-sensitive adhesive layer is laminated on a substrate, bonding the adhesive sheet onto the pressure-sensitive adhesive layer of the dicing tape to obtain a dicing tape integrated adhesive sheet, bonding a semiconductor wafer onto the adhesive sheet of the dicing tape integrated adhesive sheet, dicing the semiconductor wafer to form a semiconductor element, and picking up the semiconductor element from the pressure-sensitive adhesive layer of the dicing tape together with the adhesive sheet.

Particularly, when the adhesive sheet of the fifth aspect of the present invention is the film for a rear surface of a semiconductor, the method of manufacturing a semiconductor device includes at least the steps of preparing a dicing tape in which a pressure-sensitive adhesive layer is laminated on a substrate, bonding the film for a rear surface of a semiconductor onto the pressure-sensitive adhesive layer of the dicing tape to obtain a dicing tape integrated film for a rear surface of a semiconductor, bonding a rear surface of a semiconductor wafer onto the dicing tape integrated film for a rear surface of a semiconductor, dicing the semiconductor wafer, picking up a semiconductor element obtained by dicing, and flip-chip bonding the semiconductor element onto an adherend.

### EXAMPLES

The preferred examples of the present invention will be described in detail below. The materials, compounding amounts, and the like described in the examples are not intended to limit the scope of the invention only thereto unless specifically noted. In the examples, “parts” means “parts by weight”.

Examples 1 to 23 correspond to the first aspect of the present invention.

Examples 1 to 5 and Examples 13 to 17 correspond to the second aspect of the present invention and the third aspect of the present invention, respectively.

Examples 6 to 7 and Examples 18 to 20 correspond to the fourth aspect of the present invention and the fifth aspect of the present invention, respectively.

### Example 1

### Production of Dicing Tape

First, a substrate having a three-layered structure was produced. A substrate (may be referred to as “a laminated substrate A”) was produced in which an outermost layer (thickness: 20 μm, a polyolefin-based substrate), an intermediate layer (thickness: 40 μm, a polyolefin-based layer), and an innermost layer (thickness: 40 μm, a polyolefin-based layer) were laminated in this order. An antistatic agent (trade name: PELESTAT, produced by Sanyo Chemical Industries, Ltd.) was contained in the outermost layer in an amount of 30% by weight to the entire resin component of the outermost layer. In the present example, the innermost layer is a layer on which a pressure-sensitive adhesive layer is formed, and the outermost layer is a layer that is opposite the side where the pressure-sensitive adhesive layer is formed.

Next, 88.8 parts of 2-ethylhexyl acrylate (referred to as “2EHA” below), 11.2 parts of 2-hydroxylethyl acrylate (referred to as “HEA” below), 0.2 parts of benzoyl peroxide, and 65 parts of toluene were placed in a reactor having a condenser, a nitrogen introducing tube, a thermometer, and a stirrer, and were subjected to a polymerization treatment in a nitrogen gas flow at 61° C. for 6 hours to obtain an acryl-based polymer A having a weight average molecular weight of 850,000. The molar ratio of 2EHA to HEA was 100 mol to 20 mol.

To the acryl-based polymer A was added 12 parts of 2-methacryloyloxyethyl isocyanate (referred to as “MOI” below) (80 mol % with respect to HEA), and the resultant was subjected to an addition reaction treatment in an air flow at 50° C. for 48 hours to obtain an acryl-based polymer A′.

Then, to 100 parts of the acryl-based polymer A′ were added 8 parts of a polyisocyanate compound (trade name “Coronate L” manufactured by Nippon Polyurethane Industry Co., Ltd.) and 5 parts of a photopolymerization initiator (trade name “Irgacure 651” manufactured by Chiba Specialty Chemicals Inc.) to produce a pressure-sensitive adhesive solution (may be referred to as “a pressure-sensitive adhesive solution A”).

The pressure-sensitive adhesive solution A prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate A, and the resultant was stored at 50° C. for 24 hours. Then, only a region where a semiconductor wafer was loaded was irradiated with an ultraviolet ray of 300 mJ/cm² from the laminated substrate A side using an ultraviolet ray irradiation apparatus (trade name “UM-810” manufactured by NITTO SEIKI CO., LTD.) to obtain a dicing film (may be referred to as “a dicing tape A”).

### <Production of Adhesive Sheet>

To 100 parts of an acrylic ester-based polymer (trade name “Paracron W-197CM” produced by Negami Chemical Industrial Co., Ltd.) having ethylacrylate-methylacrylate as a main component, 113 parts of an epoxy resin (trade name “Epicoat 1004” produced by Japan Epoxy Resins Co., Ltd.), 121 parts of a phenol resin (trade name “Milex XLC-4L” produced by Mitsui Chemicals, Inc.), 246 parts of spherical silica (trade name SO-25R produced by Admatechs), 5 parts of dye 1 (trade name “OIL GREEN 502” produced by Orient Chemical Industries Co., Ltd.), and 5 parts of dye 2 (trade name “OIL BLACK BS” produced by Orient Chemical Industries Co., Ltd.) were dissolved in methylethylketone to prepare an adhesive composition solution Ahaving a concentration of solid content of 23.6% by weight.

The adhesive composition solution A was applied to a release-treated film composed of a silicon release-treated polyethylene terephthalate film having a thickness of 50 μm as a release liner (separator), and dried at 130° C. for 2 minutes to form an adhesive sheet A having a thickness (average thickness) of 20 μm.

### <Production of Dicing Tape Integrated Adhesive Sheet>

The adhesive sheet A was bonded onto the pressure-sensitive adhesive layer of the dicing tape A using a hand roller to produce a dicing tape integrated adhesive sheet A.

### Example 2

### Production of Dicing Tape

First, a substrate having a three-layered structure was produced. A substrate (may be referred to as “a laminated substrate B”) was produced in which an outermost layer (thickness: 20 μm, a polyolefin-based substrate), an intermediate layer (thickness: 40μm, a polyolefin-based layer), and an innermost layer (thickness: 40 μm, a polyolefin-based layer) were laminated in this order. An antistatic agent (trade name: PELESTAT, produced by Sanyo Chemical Industries, Ltd.) was contained in the outermost layer in an amount of 25% by weight to the entire resin component of the outermost layer.

The pressure-sensitive adhesive solution A was used as a pressure-sensitive adhesive solution.

The pressure-sensitive adhesive solution A prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate B, and the resultant was stored at 50° C. for 24 hours. Then, only a region where a semiconductor wafer was loaded was irradiated with an ultraviolet ray of 300 mJ/cm² from the laminated substrate B side using an ultraviolet ray irradiation apparatus (trade name “UM-810” manufactured by NITTO SEIKI CO., LTD.) to obtain a dicing film (may be referred to as “a dicing tape B”).

### <Production of Adhesive Sheet>

The same adhesive sheet A as in Example 1 was used as an adhesive sheet.

### <Production of Dicing Tape Integrated Adhesive Sheet>

The adhesive sheet A was bonded onto the pressure-sensitive adhesive layer of the dicing tape B using a hand roller to produce a dicing tape integrated adhesive sheet B.

### Example 3

### Production of Dicing Tape

First, a substrate having a three-layered structure was produced. A substrate (may be referred to as “a laminated substrate C”) was produced in which an outermost layer (thickness: 20 μm, a polyolefin-based substrate), an intermediate layer (thickness: 40 μm, a polyolefin-based layer), and an innermost layer (thickness: 40 μm, a polyolefin-based layer) were laminated in this order. An antistatic agent (trade name: PELESTAT, produced by Sanyo Chemical Industries, Ltd.) was contained in the outermost layer in an amount of 20% by weight to the entire resin component of the outermost layer.

The pressure-sensitive adhesive solution A was used as a pressure-sensitive adhesive solution.

The pressure-sensitive adhesive solution A prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate C, and the resultant was stored at 50° C. for 24 hours. Then, only a region where a semiconductor wafer was loaded was irradiated with an ultraviolet ray of 300 mJ/cm² from the laminated substrate C side using an ultraviolet ray irradiation apparatus (trade name “UM-810” manufactured by NITTO SEIKI CO., LTD.) to obtain a dicing film (may be referred to as “a dicing tape C”).

### <Production of Adhesive Sheet>

The same adhesive sheet A as in Example 1 was used as an adhesive sheet.

### <Production of Dicing Tape Integrated Adhesive Sheet>

The adhesive sheet A was bonded onto the pressure-sensitive adhesive layer of the dicing tape C using a hand roller to produce a dicing tape integrated adhesive sheet C.

### Example 4

### Production of Dicing Tape

First, a substrate having a three-layered structure was produced. A substrate (may be referred to as “a laminated substrate D”) was produced in which an outermost layer (thickness: 20 μm, a polyolefin-based substrate), an intermediate layer (thickness: 40 μm, a polyolefin-based layer), and an innermost layer (thickness: 40 μm, a polyolefin-based layer) were laminated in this order.

Next, a solution D for forming an antistatic agent layer was applied to the outermost layer, and it was heated and dried at 60° C. for 1 minute to form an antistatic agent layer having a thickness of about 100 nm. SEPLEGYDA (trade name, compound name: polythiophene) was used as the antistatic agent, and dispersed into a methylethylketone (MEK) solvent at a concentration of 1% to prepare the solution D for forming an antistatic agent layer.

Then, the pressure-sensitive adhesive solution A was used as a pressure-sensitive adhesive solution.

The pressure-sensitive adhesive solution A prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate D, and the resultant was stored at 50° C. for 24 hours. Then, only a region where a semiconductor wafer was loaded was irradiated with an ultraviolet ray of 300 mJ/cm² from the laminated substrate D side using an ultraviolet ray irradiation apparatus (trade name “UM-810” manufactured by NITTO SEIKI CO., LTD.) to obtain a dicing film (may be referred to as “a dicing tape D”). In the dicing tape D, an antistatic agent layer is formed on the outermost layer of the substrate.

### <Production of Adhesive Sheet>

The same adhesive sheet A as in Example 1 was used as an adhesive sheet.

### <Production of Dicing Tape Integrated Adhesive Sheet>

The adhesive sheet A was bonded onto the pressure-sensitive adhesive layer of the dicing tape D using a hand roller to produce a dicing tape integrated adhesive sheet D.

### Example 5

### Production of Dicing Tape

First, a substrate having a three-layered structure was produced. A substrate (may be referred to as “a laminated substrate E”) was produced in which an outermost layer (thickness: 20 μm, a polyolefin-based substrate), an intermediate layer (thickness: 40 μm, a polyolefin-based layer), and an innermost layer (thickness: 40 μm, a polyolefin-based layer) were laminated in this order.

Next, a solution E for forming an antistatic agent layer was applied to the outermost layer, and it was heated and dried at 60° C. for 1 minute to form an antistatic agent layer having a thickness of about 50 nm. SEPLEGYDA (trade name, compound name: polythiophene) was used as the antistatic agent, and dispersed into a MEK solvent at a concentration of 1% to prepare the solution E for forming an antistatic agent layer.

Then, the pressure-sensitive adhesive solution A was used as a pressure-sensitive adhesive solution.

The pressure-sensitive adhesive solution A prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate E, and the resultant was stored at 50° C. for 24 hours. Then, only a region where a semiconductor wafer was loaded was irradiated with an ultraviolet ray of 300 mJ/cm² from the laminated substrate E side using an ultraviolet ray irradiation apparatus (trade name “UM-810” manufactured by NITTO SEIKI CO., LTD.) to obtain a dicing film (may be referred to as “a dicing tape E”). In the dicing tape E, an antistatic agent layer is formed on the outermost layer of the substrate.

### <Production of Adhesive Sheet>

The same adhesive sheet A as in Example 1 was used as an adhesive sheet.

### <Production of Dicing Tape Integrated Adhesive Sheet>

The adhesive sheet A was bonded onto the pressure-sensitive adhesive layer of the dicing tape E using a hand roller to produce a dicing tape integrated adhesive sheet E.

### Example 6

### Production of Dicing Tape

First, a substrate having a three-layered structure was produced. A substrate (may be referred to as “a laminated substrate F”) was produced in which an outermost layer (thickness: 20 μm, a polyolefin-based substrate), an intermediate layer (thickness: 40 μm, a polyolefin-based layer), and an innermost layer (thickness: 40 μm, a polyolefin-based layer) were laminated in this order.

Then, the pressure-sensitive adhesive solution A was used as a pressure-sensitive adhesive solution.

The pressure-sensitive adhesive solution A prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate F, and the resultant was stored at 50° C. for 24 hours. Then, only a region where a semiconductor wafer was loaded was irradiated with an ultraviolet ray of 300 mJ/cm² from the laminated substrate F side using an ultraviolet ray irradiation apparatus (trade name “UM-810” manufactured by NITTO SEIKI CO., LTD.) to obtain a dicing film (may be referred to as “a dicing tape F”).

### <Production of Adhesive Sheet>

To 100 parts of an acrylic ester-based polymer (trade name “Paracron W-197CM” produced by Negami Chemical Industrial Co., Ltd.) having ethylacrylate-methylacrylate as a main component, 113 parts of an epoxy resin (trade name “Epicoat 1004” produced by Japan Epoxy Resins Co., Ltd.), 121 parts of a phenol resin (trade name “Milex XLC-4L” produced by Mitsui Chemicals, Inc.), 246 parts of spherical silica (trade name SO-25R produced by Admatechs), 5 parts of dye 1 (trade name “OIL GREEN 502” produced by Orient Chemical Industries Co., Ltd.), 5 parts of dye 2 (trade name “OIL BLACK BS” produced by Orient Chemical Industries Co., Ltd.), and 30% by weight of an antistatic agent (trade name: PELESTAT produced by Sanyo Chemical Industries, Ltd.) to the entire resin component were dissolved in methylethylketone to prepare an adhesive composition solution F having a concentration of solid content of 23.6% by weight (excluding the antistatic agent).

The adhesive composition solution F was applied to a release-treated film composed of a silicon release-treated polyethylene terephthalate film having a thickness of 50 μm as a release liner (a separator), and dried at 130° C. for 2 minutes to form an adhesive sheet F having a thickness (average thickness) of 20 μm and containing 30% by weight of PELESTAT (trade name, produced by Sanyo Chemical Industries, Ltd.) as an antistatic agent.

### <Production of Dicing Tape Integrated Adhesive Sheet>

The adhesive sheet F was bonded onto the pressure-sensitive adhesive layer of the dicing tape F using a hand roller to produce a dicing tape integrated adhesive sheet F.

### Example 7

### Production of Dicing Tape

First, a substrate having a three-layered structure was produced. A substrate (may be referred to as “a laminated substrate G”) was produced in which an outermost layer (thickness: 20 μm, a polyolefin-based substrate), an intermediate layer (thickness: 40 μm, a polyolefin-based layer), and an innermost layer (thickness: 40 μm, a polyolefin-based layer) were laminated in this order.

Then, the pressure-sensitive adhesive solution A was used as a pressure-sensitive adhesive solution.

The pressure-sensitive adhesive solution A prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate G, and the resultant was stored at 50° C. for 24 hours. Then, only a region where a semiconductor wafer was loaded was irradiated with an ultraviolet ray of 300 mJ/cm² from the laminated substrate G side using an ultraviolet ray irradiation apparatus (trade name “UM-810” manufactured by NITTO SEIKI CO., LTD.) to obtain a dicing film (may be referred to as “a dicing tape G”).

### <Production of Adhesive Sheet>

To 100 parts of an acrylic ester-based polymer (trade name “Paracron W-197CM” produced by Negami Chemical Industrial Co., Ltd.) having ethylacrylate-methylacrylate as a main component, 113 parts of an epoxy resin (trade name “Epicoat 1004” produced by Japan Epoxy Resins Co., Ltd.), 121 parts of a phenol resin (trade name “Milex XLC-4L” produced by Mitsui Chemicals, Inc.), 246 parts of spherical silica (trade name SO-25R produced by Admatechs), 5 parts of dye 1 (trade name “OIL GREEN 502” produced by Orient Chemical Industries Co., Ltd.), 5 parts of dye 2 (trade name “OIL BLACK BS” produced by Orient Chemical Industries Co., Ltd.), and 25% by weight of an antistatic agent (trade name: PELESTAT produced by Sanyo Chemical Industries, Ltd.) to the entire resin component were dissolved in methylethylketone to prepare an adhesive composition solution G having a concentration of solid content of 23.6% by weight (excluding the antistatic agent).

The adhesive composition solution G was applied to a release-treated film composed of a silicon release-treated polyethylene terephthalate film having a thickness of 50 limas a release liner (a separator), and dried at 130° C. for 2 minutes to form an adhesive sheet G having a thickness (average thickness) of 20 μm and containing 25% by weight of PELESTAT (trade name, produced by Sanyo Chemical Industries, Ltd.) as an antistatic agent.

### <Production of Dicing Tape Integrated Adhesive Sheet>

The adhesive sheet G was bonded onto the pressure-sensitive adhesive layer of the dicing tape G using a hand roller to produce a dicing tape integrated adhesive sheet G.

### Example 8

### Production of Dicing Tape Integrated Adhesive Sheet

The adhesive sheet F produced in Example 6 was bonded onto the pressure-sensitive adhesive layer of the dicing tape A produced in Example 1 using a hand roller to produce a dicing tape integrated adhesive sheet H.

### Example 9

### Production of Dicing Tape Integrated Adhesive Sheet

The adhesive sheet G produced in Example 7 was bonded onto the pressure-sensitive adhesive layer of the dicing tape B produced in Example 2 using a hand roller to produce a dicing tape integrated adhesive sheet I.

### Example 10

### Production of Dicing Tape Integrated Adhesive Sheet

The adhesive sheet F produced in Example 6 was bonded onto the pressure-sensitive adhesive layer of the dicing tape D produced in Example 4 using a hand roller to produce a dicing tape integrated adhesive sheet J.

### Example 11

### Production of Dicing Tape

First, a substrate having a three-layered structure was produced. A substrate (may be referred to as “a laminated substrate K”) was produced in which an outermost layer (thickness: 20 μm, a polyolefin-based substrate), an intermediate layer (thickness: 40 μm, a polyolefin-based layer), and an innermost layer (thickness: 40 μm, a polyolefin-based layer) were laminated in this order.

A pressure-sensitive adhesive solution K was prepared in the same manner as the pressure-sensitive adhesive solution A except that 30% by weight of PELESTAT (trade name, produced by Sanyo Chemical Industries, Ltd.) was added to the entire resin component as an antistatic agent.

The pressure-sensitive adhesive solution K prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate K, and the resultant was stored at 50° C. for 24 hours. Then, only a region where a semiconductor wafer was loaded was irradiated with an ultraviolet ray of 300 mJ/cm² from the laminated substrate K side using an ultraviolet ray irradiation apparatus (trade name “UM-810” manufactured by NITTO SEIKI CO., LTD.) to obtain a dicing film (may be referred to as “a dicing tape K”).

### <Production of Adhesive Sheet>

The same adhesive sheet A as in Example 1 was used as an adhesive sheet.

### <Production of Dicing Tape Integrated Adhesive Sheet>

The adhesive sheet A was bonded onto the pressure-sensitive adhesive layer of the dicing tape K using a hand roller to produce a dicing tape integrated adhesive sheet K.

### Example 12

### Production of Dicing Tape

First, a substrate having a three-layered structure was produced. A substrate (may be referred to as “a laminated substrate L”) was produced in which an outermost layer (thickness: 20 μm, a polyolefin-based substrate), an intermediate layer (thickness: 40 μm, a polyolefin-based layer), and an innermost layer (thickness: 40 μm, a polyolefin-based layer) were laminated in this order.

A pressure-sensitive adhesive solution L was prepared in the same manner as the pressure-sensitive adhesive solution A except that 25% by weight of PELESTAT (trade name, produced by Sanyo Chemical Industries, Ltd.) was added to the entire resin component as an antistatic agent.

The pressure-sensitive adhesive solution L prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate L, and the resultant was stored at 50° C. for 24 hours. Then, only a region where a semiconductor wafer was loaded was irradiated with an ultraviolet ray of 300 mJ/cm² from the laminated substrate L side using an ultraviolet ray irradiation apparatus (trade name “UM-810” manufactured by NITTO SEIKI CO., LTD.) to obtain a dicing film (may be referred to as “a dicing tape L”).

### <Production of Adhesive Sheet>

The same adhesive sheet A as in Example 1 was used as an adhesive sheet.

### <Production of Dicing Tape Integrated Adhesive Sheet>

The adhesive sheet A was bonded onto the pressure-sensitive adhesive layer of the dicing tape L using a hand roller to produce a dicing tape integrated adhesive sheet L.

### Example 13

A dicing tape integrated adhesive sheet according to Example 13 was prepared in the same manner as in Example 1 except that the amount of the antistatic agent to be contained in the outermost layer of the substrate was changed to 5% by weight to the entire resin component of the outermost layer. This was used as a dicing tape integrated adhesive sheet M.

### Example 14

A dicing tape integrated adhesive sheet according to Example 14 was prepared in the same manner as in Example 1 except that the amount of the antistatic agent to be contained in the outermost layer of the substrate was changed to 10% by weight to the entire resin component of the outermost layer. This was used as a dicing tape integrated adhesive sheet N.

### Example 15

A dicing tape integrated adhesive sheet according to Example 15 was prepared in the same manner as in Example 1 except that the amount of the antistatic agent to be contained in the outermost layer of the substrate was changed to 50% by weight to the entire resin component of the outermost layer. This was used as a dicing tape integrated adhesive sheet O.

### Example 16

A dicing tape integrated adhesive sheet according to Example 16 was produced in the same manner as in Example 4 except that the sheet was formed so that the thickness of the antistatic agent layer was about 20 nm. This was used as a dicing tape integrated adhesive sheet P.

### Example 17

A dicing tape integrated adhesive sheet according to Example 17 was produced in the same manner as in Example 4 except that the sheet was formed so that the thickness of the antistatic agent layer was about 150 nm. This was used as a dicing tape integrated adhesive sheet Q.

### Example 18

A dicing tape integrated adhesive sheet according to Example 18 was produced in the same manner as in Example 6 except that the amount of the antistatic agent to be contained in the adhesive sheet was changed to 5% by weight to the entire resin component of the adhesive sheet. This was used as a dicing tape integrated adhesive sheet R.

### Example 19

A dicing tape integrated adhesive sheet according to Example 19 was produced in the same manner as in Example 6 except that the amount of the antistatic agent to be contained in the adhesive sheet was changed to 10% by weight to the entire resin component of the adhesive sheet. This was used as a dicing tape integrated adhesive sheet S.

### Example 20

A dicing tape integrated adhesive sheet according to Example 20 was produced in the same manner as in Example 6 except that the amount of the antistatic agent to be contained in the adhesive sheet was changed to 50% by weight to the entire resin component of the adhesive sheet. This was used as a dicing tape integrated adhesive sheet T.

### Example 21

### Production of Dicing Tape

First, a substrate having a three-layered structure was produced. A substrate (may be referred to as “a laminated substrate U”) was produced in which an outermost layer (thickness: 20 μm, a polyolefin-based substrate), an intermediate layer (thickness: 40μm, a polyolefin-based layer), and an innermost layer (thickness: 40 μm, a polyolefin-based layer) were laminated in this order.

A pressure-sensitive adhesive solution U was prepared in the same manner as the pressure-sensitive adhesive solution A except that 5% by weight of PELESTAT (trade name, produced by Sanyo Chemical Industries, Ltd.) was added to the entire resin component as an antistatic agent.

The pressure-sensitive adhesive solution U prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate U, and the resultant was stored at 50° C. for 24 hours. Then, only a region where a semiconductor wafer was loaded was irradiated with an ultraviolet ray of 300 mJ/cm² from the laminated substrate U side using an ultraviolet ray irradiation apparatus (trade name “UM-810” manufactured by NITTO SEIKI CO., LTD.) to obtain a dicing film (may be referred to as “a dicing tape U”).

### <Production of Adhesive Sheet>

The same adhesive sheet A as in Example 1 was used as an adhesive sheet.

### <Production of Dicing Tape Integrated Adhesive Sheet>

The adhesive sheet A was bonded onto the pressure-sensitive adhesive layer of the dicing tape U using a hand roller to produce a dicing tape integrated adhesive sheet U.

### Example 22

Production of Dicing Tape

First, a substrate having a three-layered structure was produced. A substrate (may be referred to as “a laminated substrate V”) was produced in which an outermost layer (thickness: 20 μm, a polyolefin-based substrate), an intermediate layer (thickness: 40 μm, a polyolefin-based layer), and an innermost layer (thickness: 40 μm, a polyolefin-based layer) were laminated in this order.

A pressure-sensitive adhesive solution V was prepared in the same manner as the pressure-sensitive adhesive solution A except that 10% by weight of PELESTAT (trade name, produced by Sanyo Chemical Industries, Ltd.) was added to the entire resin component as an antistatic agent.

The pressure-sensitive adhesive solution V prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate V, and the resultant was stored at 50° C. for 24 hours. Then, only a region where a semiconductor wafer was loaded was irradiated with an ultraviolet ray of 300 mJ/cm² from the laminated substrate V side using an ultraviolet ray irradiation apparatus (trade name “UM-810” manufactured by NITTO SEIKI CO., LTD.) to obtain a dicing film (may be referred to as “a dicing tape V”).

### <Production of Adhesive Sheet>

The same adhesive sheet A as in Example 1 was used as an adhesive sheet.

### <Production of Dicing Tape Integrated Adhesive Sheet>

The adhesive sheet A was bonded onto the pressure-sensitive adhesive layer of the dicing tape V using a hand roller to produce a dicing tape integrated adhesive sheet V.

### Example 23

### Production of Dicing Tape

First, a substrate having a three-layered structure was produced. A substrate (may be referred to as “a laminated substrate W”) was produced in which an outermost layer (thickness: 20 μm, a polyolefin-based substrate), an intermediate layer (thickness: 40 μm, a polyolefin-based layer), and an innermost layer (thickness: 40 μm, a polyolefin-based layer) were laminated in this order.

A pressure-sensitive adhesive solution W was prepared in the same manner as the pressure-sensitive adhesive solution A except that 50% by weight of PELESTAT (trade name, produced by Sanyo Chemical Industries, Ltd.) was added to the entire resin component as an antistatic agent.

The pressure-sensitive adhesive solution W prepared above was applied to a surface of a PET release liner on which a silicone treatment was performed, and heated and crosslinked at 120° C. for 2 minutes to form a pressure-sensitive adhesive layer having a thickness of 30 μm. After that, the pressure-sensitive adhesive layer side was bonded to the surface of the innermost layer of the laminated substrate W, and the resultant was stored at 50° C. for 24 hours. Then, only a region where a semiconductor wafer was loaded was irradiated with an ultraviolet ray of 300 mJ/cm² from the laminated substrate W side using an ultraviolet ray irradiation apparatus (trade name “UM-810” manufactured by NITTO SEIKI CO., LTD.) to obtain a dicing film (may be referred to as “a dicing tape W”).

### <Production of Adhesive Sheet>

The same adhesive sheet A as in Example 1 was used as an adhesive sheet.

### <Production of Dicing Tape Integrated Adhesive Sheet>

The adhesive sheet A was bonded onto the pressure-sensitive adhesive layer of the dicing tape W using a hand roller to produce a dicing tape integrated adhesive sheet W.

### <Measurement of Peeling Electrification Voltage>

The dicing tape integrated adhesive sheet was bonded to an acrylic plate 100 (thickness: 1 mm, width: 70 mm, length: 100 mm) that had been destaticized in advance. The bonding was performed using a hand roller so that the acrylic plate and the substrate of the dicing tape integrated adhesive sheet were facing each other with a double-sided pressure-sensitive adhesive tape interposed therebetween.

A sample was allowed to stand under environments of 23° C. and 50% RH for a day, and set to a prescribed position (see FIG. 2). An end portion of the adhesive sheet was fixed to an automatic winding machine, and the sheet was peeled off at a peeling angle of 150° and a peeling rate of 10 m/minute. A potential of a surface of the pressure-sensitive adhesive layer side generated at this time was measured with a potential measuring machine (“KSD-0103” manufactured by Kasuga Electric Works Ltd.) fixed at a prescribed position. The measurement was performed under environments of 23° C. and 50% RH. The results are shown in Table 1.

### <Measurement of Peeling Force>

A rectangular test piece having a size of 100 mm long and 20 mm wide was cut out from the dicing tape integrated adhesive sheet. The test piece was lined with an SUS plate, and the adhesive sheet was peeled from the dicing tape (that is, from the pressure-sensitive adhesive layer of the dicing tape) (peeled off the adhesive sheet at the interface with the pressure-sensitive adhesive layer) at a temperature of 23° C. under conditions of a peeling angle of 90° and a tensile rate of 300 mm/minute using a peeling tester (trade name “AUTOGRAPH AGS-J” manufactured by SHIMADZU CORPORATION). The maximum load during peeling (maximum value of the load excluding the peak top at the beginning of the measurement) was measured to be the peeling force between the adhesive sheet and the pressure-sensitive adhesive layer of the dicing tape (the adhering strength of the pressure-sensitive adhesive layer of the dicing tape to the adhesive sheet) (the adhering strength; N/20 mm width). The results are shown in Table 1.

### <Measurement of Surface Resistivity>

The surface resistivity was measured of the surface of the outermost layer side of the dicing tape for Examples 1 to 5 and 13 to 17, the surface of the side of the adhesive sheet that contacts to the dicing tape for Examples 6 and 7 and 18 to 20, the outermost layer of the dicing tape, the surface of the side of the protective film of a rear surface of a semiconductor that contacts to the dicing tape for Examples 8 to 10, and the surface of the pressure-sensitive adhesive layer of the dicing tape for Examples 11 and 12 and 21 to 23. The surface resistivity was measured by applying a DC voltage of 100 V for 1 minute under conditions of 23° C. and 60% RH using a sample box TR-42 for measuring ultra high resistance with a high megohm meter TR-8601 manufactured by Advantest Corporation. The results are shown in Table 1.

TABLE 1

| | | Peeling | Peeling |
|---|---|---|---|
| | | Electrification | Force |
| | Surface Resistivity [Ω] | Voltage [kV] | [N/20 mm] |
| Example 1 | 5.0 × 10⁸ | 0.03 | 0.1 |
| Example 2 | 8.0 × 10⁸ | 0.04 | 0.1 |
| Example 3 | 1.0 × 10⁹ | 0.05 | 0.1 |
| Example 4 | 1.0 × 10⁸ | 0.01 | 0.1 |
| Example 5 | 3.0 × 10⁸ | 0.02 | 0.1 |
| Example 6 | 5.0 × 10⁸ | 0.03 | 0.1 |
| Example 7 | 8.0 × 10⁸ | 0.04 | 0.1 |
| Example 8 | Outermost Layer: 5.0 × 10⁸ | 0.01 | 0.1 |
| | Adhesive Sheet: 5.0 × 10⁸ | | |
| Example 9 | Outermost Layer: 8.0 × 10⁸ | 0.01 | 0.1 |
| | Adhesive Sheet: 8.0 × 10⁸ | | |
| Example 10 | Outermost Layer: 1.0 × 10⁸ | 0.01 | 0.1 |
| | Adhesive Sheet: 5.0 × 10⁸ | | |
| Example 11 | 5.0 × 10⁸ | 0.03 | 0.1 |
| Example 12 | 8.0 × 10⁸ | 0.04 | 0.1 |
| Example 13 | 1.0 × 10¹¹ | 0.5 | 0.1 |
| Example 14 | 1.0 × 10¹⁰ | 0.1 | 0.1 |
| Example 15 | 3.0 × 10⁸ | 0.02 | 0.1 |
| Example 16 | 1.0 × 10⁹ | 0.05 | 0.1 |
| Example 17 | 8.0 × 10⁷ | 0.01 | 0.1 |
| Example 18 | 1.0 × 10¹¹ | 0.5 | 0.1 |
| Example 19 | 1.0 × 10¹⁰ | 0.1 | 0.1 |
| Example 20 | 3.0 × 10⁸ | 0.02 | 0.1 |
| Example 21 | 2.0 × 10¹¹ | 0.5 | 0.1 |
| Example 22 | 1.0 × 10¹⁰ | 0.1 | 0.1 |
| Example 23 | 4.0 × 10⁸ | 0.02 | 0.1 |

What is claimed is:

1. A dicing tape integrated adhesive sheet comprising a substrate, a dicing tape in which a pressure-sensitive adhesive layer is laminated on the substrate, and an adhesive sheet formed on the pressure-sensitive adhesive layer, wherein
a peeling force between the pressure-sensitive adhesive layer and the adhesive sheet is 0.02 to 0.5 N/20 mm obtained with a peeling test at a peeling rate of 10 m/minute and a peeling angle of 150°, and
an absolute value of a peeling electrification voltage is 0.5 kV or less when the pressure-sensitive adhesive layer and the adhesive sheet are peeled off under conditions of the peeling test.

2. The dicing tape integrated adhesive sheet according to claim 1, wherein the adhesive sheet is a film for a rear surface of a flip-chip semiconductor to be formed on a rear surface of a semiconductor element that is flip-chip bonded on an adherend.

3. The dicing tape integrated adhesive sheet according to claim 1, wherein an antistatic agent is contained in the substrate.

4. The dicing tape integrated adhesive sheet according to claim 3, wherein the substrate has a multilayered structure, and an antistatic agent is contained in at least one of outermost layers of the multilayered substrate.

5. The dicing tape adhesive sheet according to claim 1, wherein an antistatic agent layer containing an antistatic agent is formed on at least one of surfaces of the substrate.

6. The dicing tape integrated adhesive sheet according to claim 1, wherein an antistatic agent is contained in the pressure-sensitive adhesive layer.

7. The dicing tape integrated adhesive sheet according to claim 1, wherein an antistatic agent is contained in the adhesive sheet.

8. A method of manufacturing a semiconductor device using the dicing tape integrated adhesive sheet according to claim 1, the method comprising the steps of:
bonding a semiconductor wafer onto the adhesive sheet of the dicing tape integrated adhesive sheet,
dicing the semiconductor wafer to form a semiconductor element, and
picking up the semiconductor element from the pressure-sensitive adhesive layer of the dicing tape together with the adhesive sheet.

9. A semiconductor device, which is manufactured by using the dicing tape integrated adhesive sheet according to claim 1.
